(19) United States
(12) Patent Application Publication
(10) Pub. No.: US 2007/0032033 A1
(43) Pub. Date: Feb. 8, 2007

(54) Connecting structure and method for manufacturing the same

(76) Inventors: Lars Heineck, Dresden (DE); Martin Popp, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/493,931

(22) Filed: Jul. 27, 2006

Related U.S. Application Data
(63) Continuation-in-part of application No. 11/356,459, filed on Feb. 17, 2006.

(30) Foreign Application Priority Data
Aug. 3, 2005 (DE) 102005036561.2

(51) Int. Cl. H01L 21/20

(52) U.S. Cl. 438/386

(57) ABSTRACT

A connecting structure connects a storage electrode of a trench capacitor and a selection transistor that are at least partially formed in a semiconductor substrate. The connecting structure includes a portion of an intermediate layer disposed adjacent to a surface of the storage electrode, and an electrically conducting material disposed adjacent to the intermediate layer and electrically connected to a semiconductor substrate surface portion adjacent to the selection transistor, wherein a part of the connecting structure is disposed above the semiconductor substrate surface so as to be adjacent to a horizontal substrate surface portion.

### CROSS-REFERENCE TO RELATED APPLICATIONS

This application is a Continuation-in-Part of U.S. application Ser. No. 11/356,459, filed on Feb. 17, 2006, which claims priority under 35 U.S.C. §119 to German Application No. DE 10 2005 036 561.2, filed on Aug. 3, 2005, and titled “Connecting Structure and Method for Manufacturing a Connecting Structure,” the entire contents of which are hereby incorporated by reference.

### FIELD OF THE INVENTION

This invention relates to a method for manufacturing a connecting structure between a trench capacitor and an access transistor as well as to a corresponding connecting structure.

### BACKGROUND OF THE INVENTION

Memory cells of dynamic random access memories (DRAMs) generally comprise a storage capacitor and an access transistor. The storage capacitor stores information in the form of an electrical charge representing a logical value 0 or 1. By controlling the readout or, respectively, the access transistor via a word line, the information stored in the storage capacitor can be read out via a bit line. For secure storage of the charge and to permit discrimination of the read-out information, the storage capacitor must have a minimum capacity. Accordingly, the lower limit for the capacity of the storage capacitor is considered to be approximately 25 fF.

FIG. 1 shows diagrammatically the schematic of a DRAM memory cell 5 with a storage capacitor 3 and an access transistor 16. The access transistor 16 is preferably designed as a n-channel field effect transistor (FET) and comprises a first n-doped source/drain region 121 and a second n-doped source/drain region 122 between which an active, weakly p-conducting channel area 14 is provided. Above the channel area 14, a gate insulator layer 151 is provided above which a gate electrode 15 is arranged by which the charge carrier density in the channel area 14 can be influenced.

The first source/drain region 121 of the access transistor 16 is connected via a connection area 46 to the storage electrode 31 of the storage capacitor 3. A counter-electrode 34 of the storage capacitor is, in turn, connected to a capacitor plate 36 which is preferably common to all storage capacitors of a DRAM memory cell array. A capacitor dielectric 33 is provided between storage electrode 31 and counter-electrode 34.

The second source/drain region 122 of the access transistor 16 is connected via a bit line contact 53 with a bit line 52. Via the bit line, the information stored in the storage capacitor 3 in the form of charges can be written in and read out. A write-in or read-out process is controlled via a word line 51 which is connected with the gate electrode 15 of the access transistor 16, with a current-conducting channel being provided by applying a voltage in the channel area 14 between the first source/drain region 121 and the second source/drain region 122. Furthermore, a substrate connection 54 is provided to prevent the semiconductor substrate from being charged during the on and off switching operations of the transistor.

Since the storage density increases from memory generation to memory generation, the required area of the single transistor memory cell must be reduced from one generation to the next. At the same time, the minimum capacity of the storage capacitor must be maintained.

Up to the 1 Mbit generation, the read-out transistor as well as the storage capacitor were realized as planar components. As of the 4 Mbit memory generation, further surface reduction of the memory cell has been achieved through a three-dimensional arrangement of the storage capacitor. One possibility consists of realizing the storage capacitor in a trench. Acting as electrodes of the storage capacitor are, for example, in this case, a diffusion area adjacent to the wall of the trench, as well as a doped polysilicon filling in the trench. Thus, the electrodes of the storage capacitor are arranged along the surface of the trench. The effective area of the storage capacitor, on which the capacity depends, will thereby be increased relative to the space requirement for the storage capacitor on the surface of the substrate which corresponds to the cross-section of the trench. By a reduction of the cross-section of the trench with a simultaneous increase of its depth, the packing density can be further increased.

For a further reduction of the memory cell size, it is particularly desirable to reduce the lithographic structural size F. F is the minimum line width of a structural size that can be structured with the lithography currently used. In particular, it is required for a further reduction of the memory cell size to reduce the lateral extension of the transistor as far as possible. In particular, the length of the channel 14 adjacent the gate electrode will be reduced thereby. However, shortening this channel length results in an increase of leakage currents between storage capacitor 3 and bit line 52. Overall, a reduced channel length can result in an impairment of the low threshold leakage current and thus the retention time, i.e., the time within which information can again be recognizably stored in the memory cell.

To address the described problems, it has been proposed to provide the gate electrode in a groove formed in the substrate surface so that the channel comprises vertical and horizontal components in relation to the substrate surface. The effective channel length can thereby be increased, with unchanged space requirement for the access transistor, thus reducing the leakage current.

The connection of the storage electrode of the trench capacitor 3 to the first source/drain region of the access transistor is customarily accomplished via a so-called buried strap connection which is provided below the substrate surface. To be able to better utilize the advantages achieved with an access transistor in which the gate electrode is arranged in a groove, it is necessary to realize the connection of the storage electrode of the trench capacitor as far as possible in the vicinity of the surface of the substrate. In particular, a so-called surface strap connection is desirable which is formed above the substrate surface. Usually, such connections are unilaterally formed, i.e., only on one side of the trench capacitor 3. Thus, as a rule, the provision of a buried strap or surface strap connection presents a break in the symmetry because, after this connection is formed, the trench capacitor is no longer symmetrical with regard to an axis which extends perpendicularly to the direction of the active areas and, respectively, the channel 14.

### SUMMARY

According to the invention, an improved connecting structure between a storage electrode of a trench capacitor and a selection transistor that are at least partially formed in a semiconductor substrate comprises a portion of an intermediate layer disposed adjacent to a surface of the storage electrode, and an electrically conducting material disposed adjacent to the intermediate layer and electrically connected to a semiconductor substrate surface portion adjacent to the selection transistor, wherein a part of the connecting structure is disposed above the semiconductor substrate surface so as to be adjacent to a horizontal substrate surface portion.

Moreover, a connecting structure between a storage electrode of a trench capacitor and a selection transistor that are at least partially formed in a semiconductor substrate comprises a portion of an intermediate layer disposed adjacent to a surface of the storage electrode, and an electrically conducting material disposed adjacent to the intermediate layer and electrically connected to a semiconductor substrate surface portion adjacent to the selection transistor, wherein the storage electrode is laterally delimited by a trench formed in the substrate surface, the electrically conducting material being disposed at least partially outside this trench.

Furthermore, a connecting structure between a storage electrode of a trench capacitor and a selection transistor that are at least partially formed in a semiconductor substrate, wherein an isolating trench is disposed adjacent to a vertical surface of the storage electrode, the isolating trench being arranged between the storage electrode and the semiconductor substrate, an insulating material being disposed in the isolating trench, wherein the connecting structure comprises a strap of a conductive material which is disposed in the isolating trench.

In addition, a method of manufacturing a connecting structure between a storage electrode of a trench capacitor and a selection transistor comprises providing a capacitor trench in a semiconductor substrate, the trench capacitor comprising a conductive filling, a vertical insulating layer being disposed adjacent to a lateral surface of the conductive filling, providing a masking material on a surface of the semiconductor substrate, the masking material being provided on areas of the substrate surface in which no trench capacitor is formed, wherein a surface of the conductive filling of the trench capacitor is disposed beneath a surface of the masking material, depositing a semiconductor layer that is undoped, the semiconductor layer comprising vertical and horizontal areas, performing oblique ion implantation such that a predetermined area of the semiconductor layer remains undoped, removing an undoped portion of the semiconductor layer, with a doped portion of the semiconductor layer remaining on a surface of the masking material, thereby leaving a surface of the vertical insulating layer uncovered, etching an upper portion of the vertical insulating layer, thereby forming a connection opening, filling a conductive material in the connection opening, and removing the masking layer thereby exposing a semiconductor substrate surface portion.

The above and still further features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein

### BRIEF DESCRIPTION OF THE DRAWINGS

In the following, the invention will be described in detail with reference to the accompanying drawings.

FIG. 1 illustrates a schematic of a DRAM memory cell.

FIGS. 2A and 2B respectively illustrate a top plan view and a cross-sectional side view in elevation of a completely processed storage capacitor.

FIGS. 3A to 13B illustrate manufacturing stages of forming the connecting structure according to a first embodiment of the present invention.

FIG. 14 is a cross-sectional side view in elevation of memory cells with completed connecting structure in accordance with the first embodiment of the present invention.

FIGS. 15A to 29 illustrate manufacturing stages of forming the connecting structure according to a second embodiment of the present invention.

FIG. 30 is a cross-sectional side view in elevation of memory cells with a completed connecting structure in accordance with the second embodiment.

FIGS. 31 to 41 illustrate manufacturing stages of forming the connecting structure according to a third embodiment of the present invention.

FIG. 42 is a top plan view of a memory cell array with connecting structures according to an exemplary embodiment of the present invention.

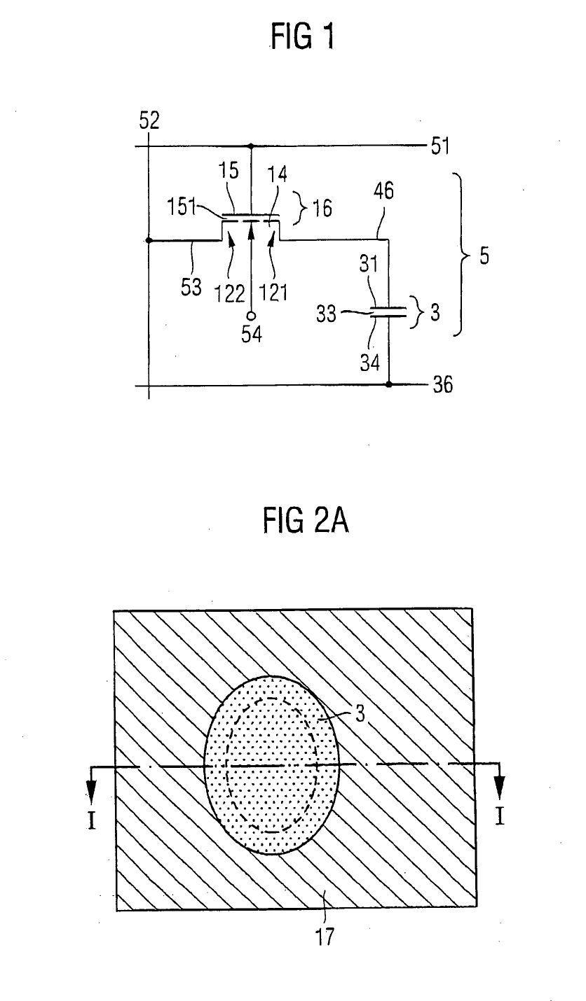

### DETAILED DESCRIPTION OF THE DRAWINGS

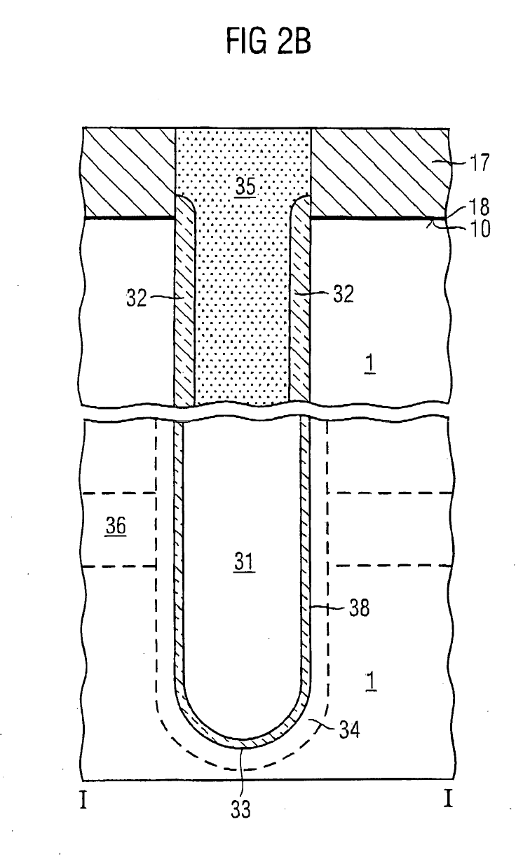

FIGS. 2A and 2B respectively present a top plan view and a cross-sectional side view in elevation of a storage capacitor which is provided in a trench 38 formed in a semiconductor substrate 1, for example, a silicon substrate. The trench normally has a depth of 6 to 7 μm and can be designed as illustrated in FIG. 2B in cross section, or it can be widened in its lower portion.

As illustrated in FIG. 2A, the larger diameter of the capacitor trench is typically 2 F while the smaller diameter is 1.5 F. F is the minimum structural size and can currently be 90 to 110 nm and especially less than 90 nm. FIG. 2B is a cross-sectional view along line I-I as illustrated in FIG. 2A. The counter-electrode 34 of the storage capacitor is realized, for example, by an n+ doped substrate portion. In the trench 38 are arranged, moreover, a capacitor dielectric 33 as normally used, as well as a polysilicon filling 31 as a storage electrode. The upper trench portion provides an isolation collar 32 for turning off a parasitic transistor which would otherwise develop at this point.

Moreover, in the upper portion of the capacitor trench 38, a polysilicon filling 35 is provided. In the substrate, an n+ doped area is furthermore provided as a buried plate connection 36 which connects the counter electrodes of the trench capacitors with each other. On the substrate surface 10, a SiO₂ layer 18 as well as a Si₃N₄ layer 17 is applied as a pad nitride layer. The SiO₂ layer 18 typically comprises a layer thickness of about 4 nm; the Si₃N₄ layer 17 typically a layer thickness of 80 to 120 nm.

The trench capacitor presented in FIGS. 2A and 2B is manufactured according to known methods. In particular, the isolation collar 32 is manufactured as usual. Subsequently, the isolation collar 32 is etched back so that the upper edge of the isolation collar is disposed above the substrate surface 10. Subsequently, the capacitor trench 38 is filled with polysilicon, and a CMP (chemical mechanical polishing) step is performed so that the cross-section shown in FIG. 2B results.

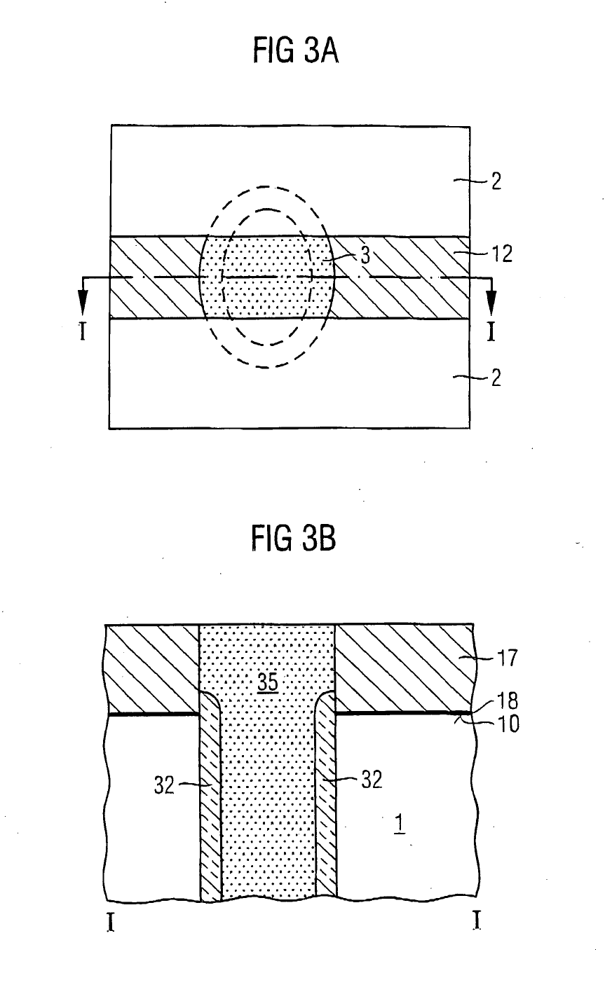

Referring to FIGS. 3A and 3B, for the definition of the active areas 12, isolation trenches 2 next are formed, which will be filled up with an insulating material, in particular silicon dioxide. After etching the isolation trenches 2 and filling up the isolation trenches 2 with the insulating material, removal of surface oxide is performed. FIG. 3A shows a top view on the resulting trench capacitor 3 with the isolation trenches 2, and FIG. 3B shows a cross-sectional view along the line connecting the points I and I with each other.

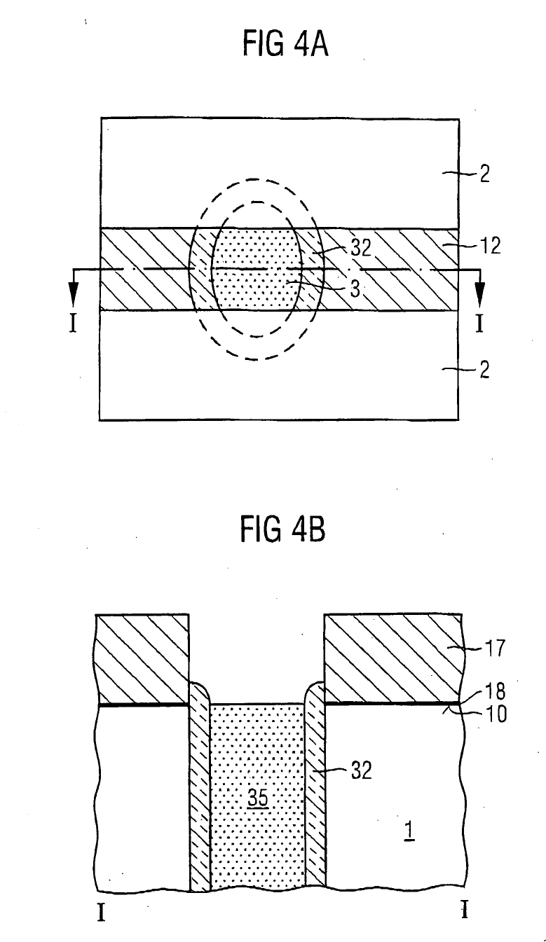

Subsequently, the polysilicon 35 filled into the capacitor trench 38 is etched back up to approximately the level of the substrate surface 10, and the structure shown in FIGS. 4A and 4B results. FIG. 4A shows a top view on the resulting trench capacitor. As shown in FIG. 4A, the surface of the isolation collar 32 is now exposed. FIG. 4B shows a cross-sectional view along the line connecting the points I and I in FIG. 4A with each other. As shown in FIG. 4B, the surface of the isolation collar 32 is now above the surface of the polysilicon filling 35.

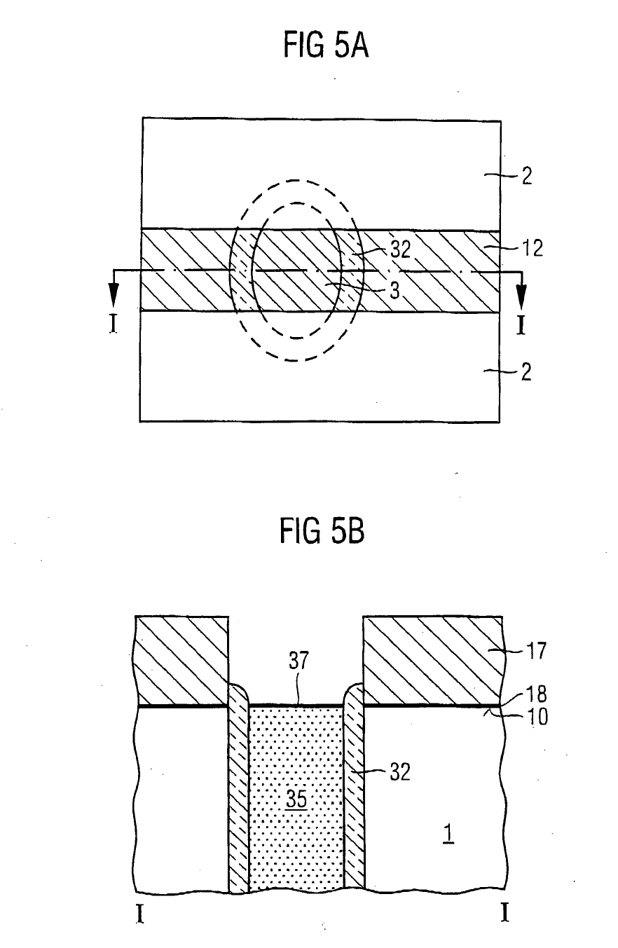

As shown in FIGS. 5A and 5B, a nitridation step as generally known is then performed. Here, a thin Si₃N₄ layer 37, typically with a thickness of up to 1 nm, is formed such that the substrate surface is exposed to an NH₃ atmosphere. This Si₃N₄ layer 37 serves as an etching stop layer with a subsequent etching step for etching the undoped amorphous semiconductor layer 4. FIG. 5B shows the silicon nitride layer 37 in the cross-section along line I-I, as presented in FIG. 5A.

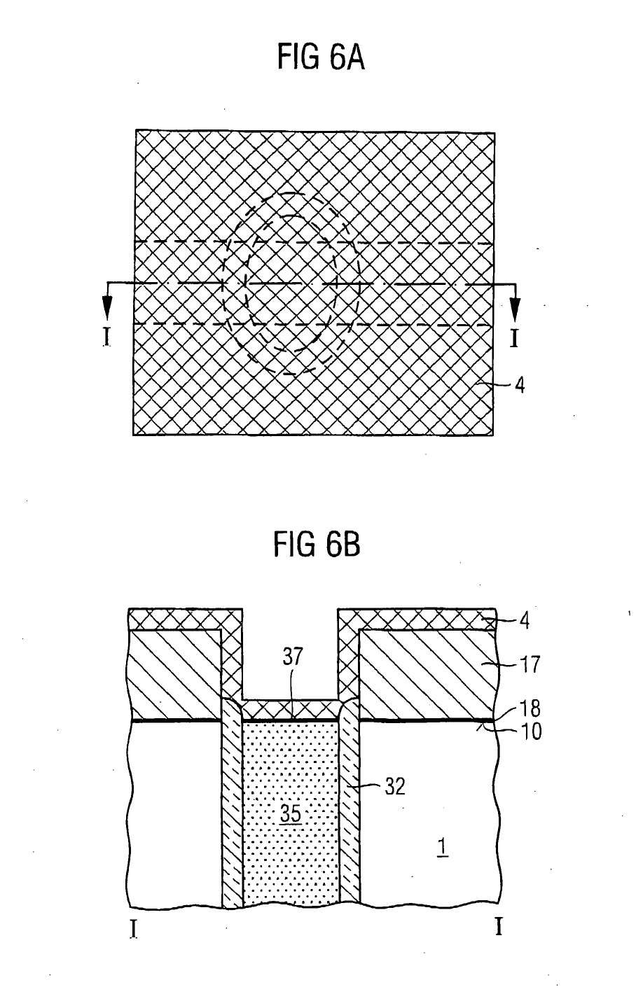

As shown in FIGS. 6A and 6B, an undoped amorphous semiconductor layer, preferably an undoped amorphous silicon layer, for example with a layer thickness of 10 nm, then is conformally deposited. As a result, the deposited silicon layer 4, as presented in FIG. 6B in cross-section, comprises vertical and horizontal areas. FIG. 6A shows a top view of the resulting structure.

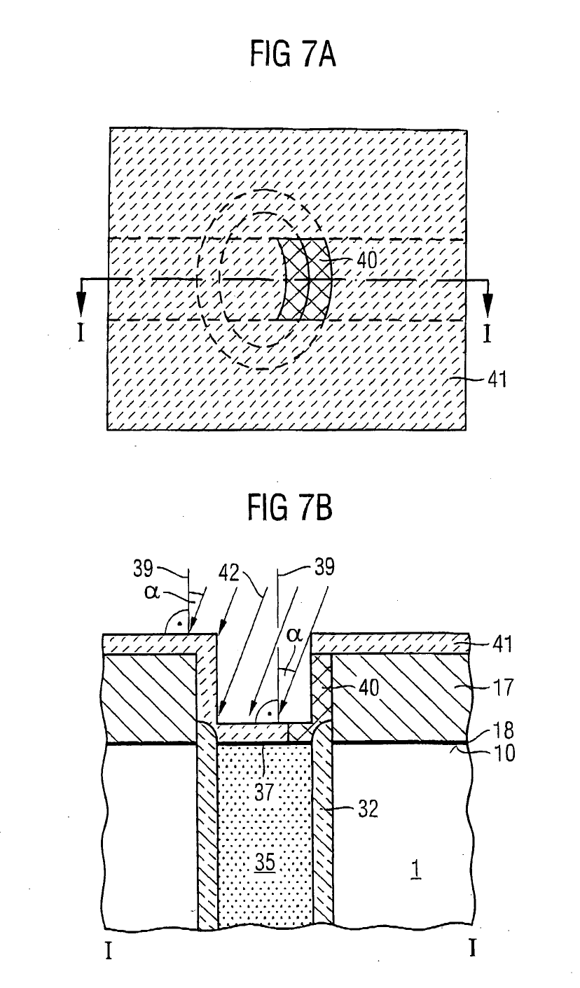

Referring to FIGS. 7A and 7B, an ion implantation step is then performed with B+ or BF2+ ions with an oblique angle of incidence of the ion beam 42. For example, the ion beam 42 has an angle α of 5 to 25 degrees, in particular 10 to 15 degrees, in reference to the normal 39 to the substrate surface 10. As a result of the oblique ion implantation and the fact that the amorphous silicon layer 4 has vertical areas, one part of the amorphous silicon layer 4 is shaded in this implantation step. The oblique ion implantation is arranged such that the shaded area is at the point in which the surface connection or, respectively, the connecting structure is to be made. Due to the fact that the vertical area of the amorphous silicon layer 4 is shaded by the capacitor trench wall, asymmetrical processing will now take place. Consequently, the capacitor trench with connecting structure is now no longer symmetrical with regard to an axis which extends perpendicularly to the channel of the access transistor to be manufactured.

The structure shown in FIGS. 7A and 7B results, with FIG. 7A presenting a top view, whereas FIG. 7B illustrates a cross-sectional view along line I-I as in FIG. 7A. In particular, one part of the amorphous silicon layer 4 remains undoped, whereas the remaining areas having been exposed to the ion beam 42 will be doped. As illustrated in FIG. 7A, one section of the contour of the capacitor trench 38 remains undoped.

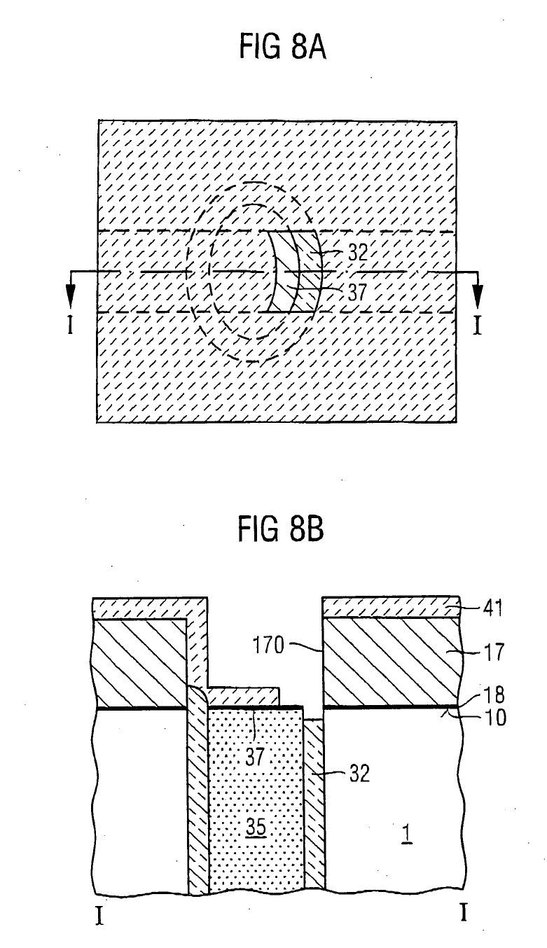

Referring to FIGS. 8A and 8B, the undoped amorphous silicon 4 is then selectively removed in relation to the p-doped polysilicon which has resulted due to the ion implantation. This can be done, for example, by chemical wet etching in diluted NH4OH.

As presented in FIG. 8A which is a top view on the resulting structure, one part of the silicon nitride layer 37 is now exposed. As is especially evident from FIG. 8B showing a cross-sectional view along line I-I in FIG. 8A, the lateral flank or sidewall, respectively, of the Si₃N₄ layer 17 is exposed especially. As an optional process step, the isolation collar 32 can furthermore be etched back somewhat so that the surface of the isolation collar 32 is, on one side, below the substrate surface 10.

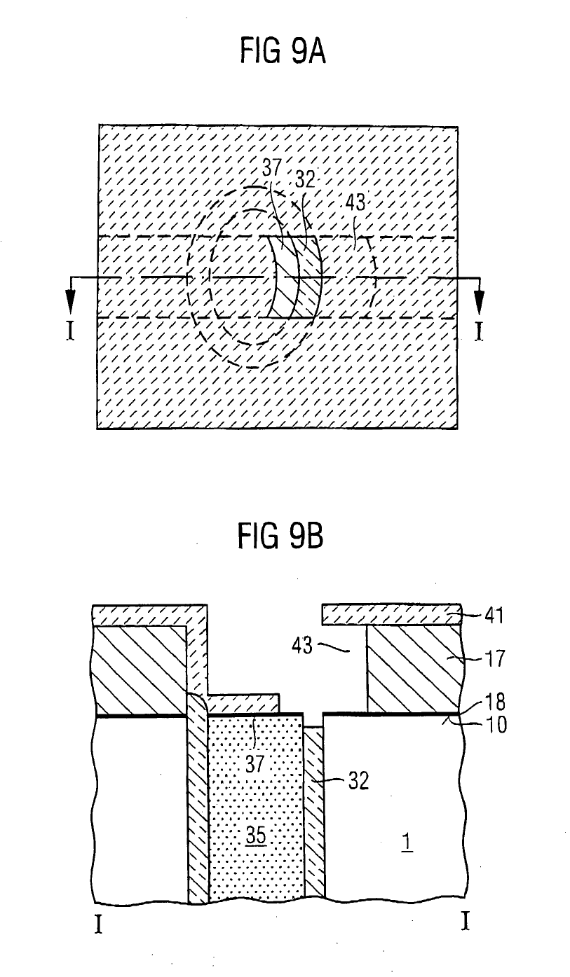

Referring next to FIGS. 9A and 9B, the Si₃N₄ layer 17 is then etched back by an isotropic etching step. This can be done, for example, by wet etching in hot phosphoric acid (hot phos). Due to this etching step, the Si₃N₄ layer 17 is particularly laterally etched so that, as a result, a horizontal section of the SiO₂ layer 18 is exposed FIG. 9A shows a top view on the resulting trench capacitor in which the opening 43 produced by the preceding Si₃N₄ etching step is indicated in dashed lines. FIG. 9B shows a cross-section along line I-I. As seen here, an opening 43 is produced by which one part of the SiO₂ layer 18 arranged on the substrate surface 10 has been exposed.

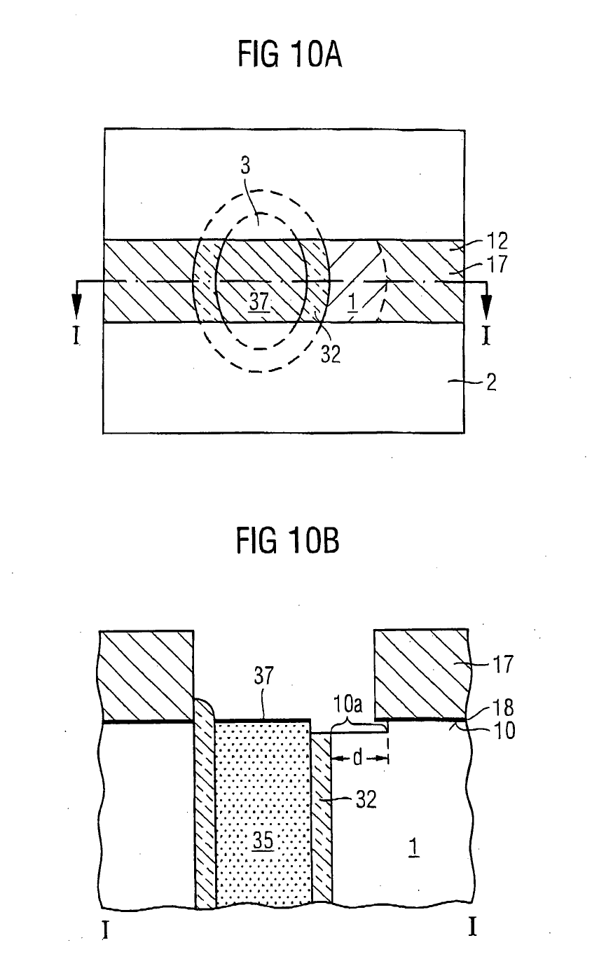

As shown in FIGS. 10A and 10B, in a next step, the p-doped polysilicon 41 is removed, for example, by a reactive ion etching process. In this step, the exposed part of the silicon substrate 1 will also be etched. Care should here be taken that not too much silicon substrate material is etched off. Underneath the opening 43, as presented in FIGS. 9A and 9B, an exposed Si surface area 10a will now be formed with a width d from 10 to 100 nm, as indicated in FIG. 10B. In particular, in this etching step, by choosing appropriate etching parameters, it is determined whether the conducting material and, thus, the connection will be disposed essentially above or essentially below the substrate surface.

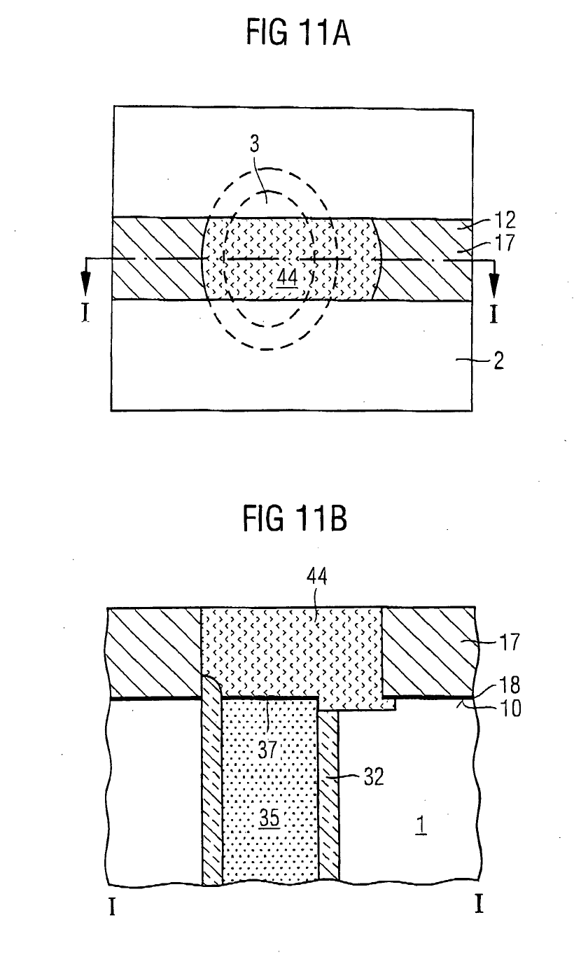

FIG. 10A shows a top view on the resulting structure. As shown in FIG. 10B, a surface section 10a of the semiconductor substrate 1 is now exposed. This surface area is exposed only on one side of the trench capacitor 3. Thus, the trench capacitors with the processed connecting structures are now no longer symmetrical with regard to an axis running perpendicularly to the active regions 12. Above the polysilicon filling 35, a thin silicon nitride layer 37 is provided. As shown in FIGS. 11A and 11B, in a next step, a polysilicon layer 44 is applied and subsequently planarized, for example, by a CMP step or an etch-back step. The deposited polysilicon 44 can either be doped in situ or doped by an implantation process after termination of the deposition step.

As shown in FIG. 11A, a contact strap is now provided between the polysilicon filling 35 connected with the storage electrode 31 and the active area 12 adjacent to the trench capacitor 3. FIG. 11B shows a cross-sectional view along the line connecting the points I and I with each other. As can be seen, a polysilicon filling 44 is connected with the silicon substrate 1 and lies on top of the Si₃N₄ layer 37 which is provided on the polysilicon filling 35.

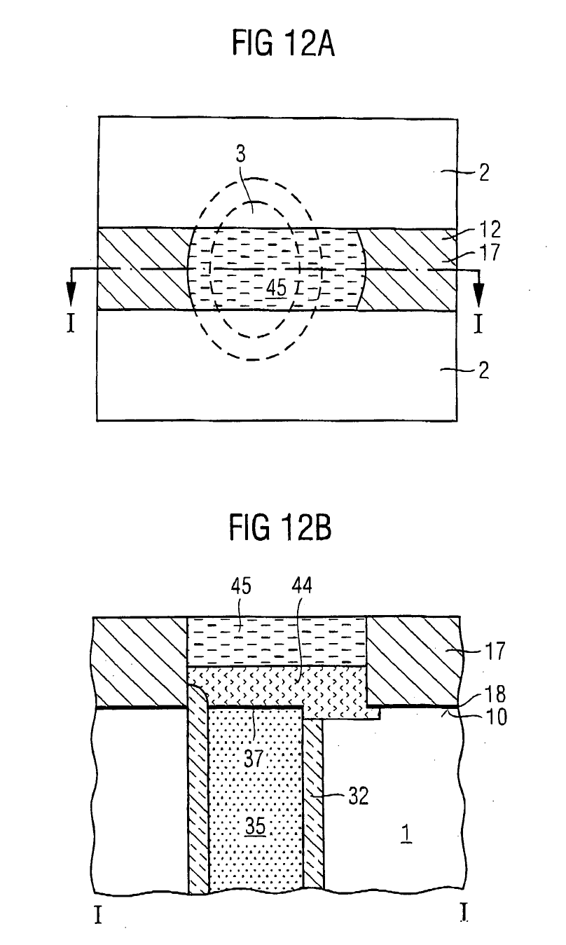

Referring to FIGS. 12A and 12B, in a next step, an oxidation layer is generated which insulates the produced surface strap connection towards the top. In particular, by this step the position of the upper edge of the polysilicon layer 44 will be determined. This can be done, for example, by the surface shown in FIG. 11A being exposed to a highly oxidizing atmosphere so that an oxide layer will be produced by oxidation, the silicon dioxide layer 45 being provided on the polysilicon filling 44. In particular, the layer thickness of the silicon dioxide layer 45—produced on the polysilicon filling—amounts to at least 15 nm. Alternatively, the polysilicon layer 44 presented in FIG. 11B can also be etched back. Subsequently, a step is performed for producing a SiO2 filling on the polysilicon layer 44, and a CMP step will be performed for planarization of the surface.

Finally, the structure presented in FIGS. 12A and 12B will result. FIG. 12A shows a top view with the surface essentially being composed of SiO₂ as well as of Si₃N₄ in some areas. FIG. 12B shows a cross-sectional view along the line between I and I. As shown in FIG. 12B, a SiO₂ covering layer 45 is now applied on the polysilicon layer 44.

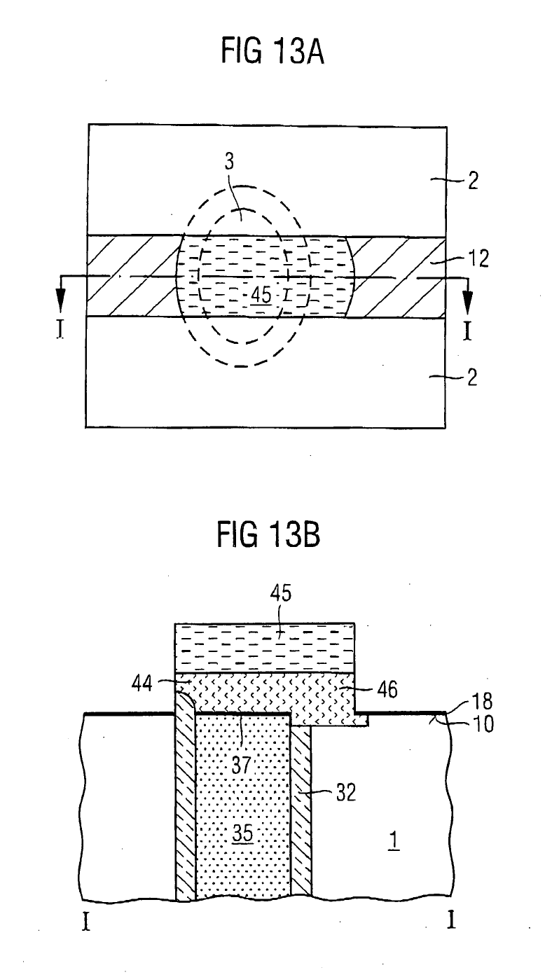

In a next step, the Si₃N₄ layer 17 and subsequently the SiO₂ layer 18 will be removed according to known methods. As a result, the structure shown in FIGS. 13A and 13B will be provided. FIG. 13A shows a top view on the resulting structure. In the still unprocessed area of the active area 12, silicon is exposed while the remaining part of the structure is covered by an SiO₂ layer. As results from the cross-sectional view of FIG. 13B, a unilateral surface strap connection 46 is now realized between the polysilicon filling 35 and the single crystal semiconductor material 1. More precisely, the connection 46 is arranged between the polysilicon filling 35 and the substrate material 1 above the substrate surface 10. The thin Si₃N₄ layer 37 acts merely as a tunnel barrier; not, however, as an insulator. The polysilicon layer 44 is covered by a SiO2 layer 45.

For completion of the memory cell, the components of the access transistor are subsequently provided, in particular by processing the gate electrode 15, as well as the first and second source/drain region 121, 122. For this, the layers normally used for the gate stack will first be conformally deposited and thereafter patterned for producing the gate electrodes 15. In particular, a gate oxide layer 151 is first produced. The deposited SiO2 layer also serves as a lateral insulation of the surface strap connection 46. Subsequently, a conducting layer, for example of polysilicon as well as a Si₃N₄ capping layer 152 will be deposited. Thereafter, the gate electrode 15 is patterned according to a known method. By using the produced gate electrodes, as well as the surface strap connection as an implantation mask, the first and the second source/drain region 121, 122 will be subsequently produced through ion implantation. Due to the temperature increase connected with the ion implantation step, doping substances also diffuse from the doped polysilicon material 45 into the substrate material and will there form the doped region 120. The doped region 120 effects a good electrical contact between the surface strap connection 46 and the first source/drain region 121, 122.

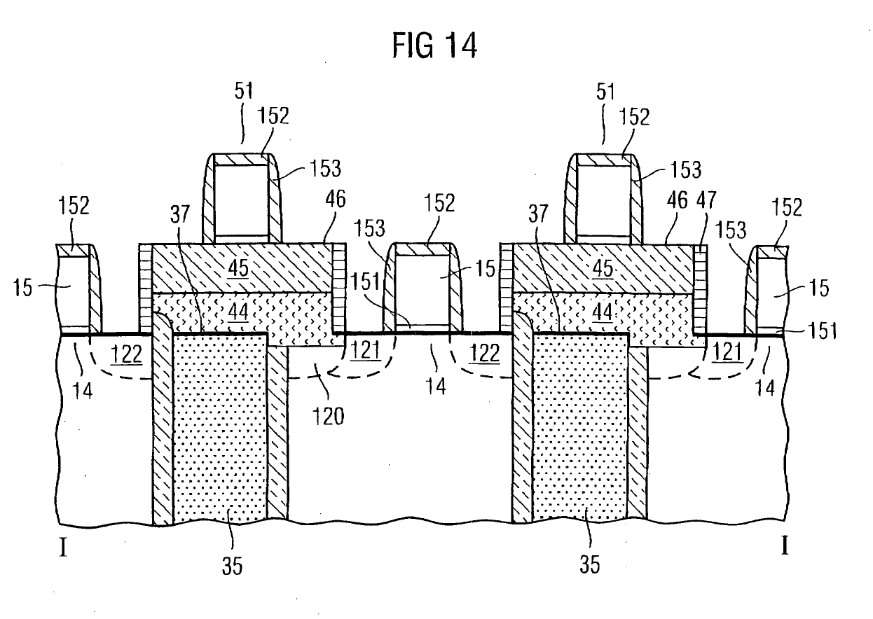

FIG. 14 shows an exemplified cross-sectional view through the resulting memory cell array. In the presented layout, the passing word lines are each arranged above the surface strap connection 46, as is generally standard. The passing word lines are each adequately insulated by the SiO2 layer 45 from the surface strap connection. Although a planar access transistor is illustrated in FIG. 14, it is clear that any designs of the access transistor can be connected via the connecting structure according to the invention with the storage electrode of a storage capacitor. In particular, such access transistors can be those wherein the channel also comprises a vertical component in relation to the substrate surface; thus, in particular, those in which the gate electrode is provided in a groove formed in the substrate surface. The connecting structure shown in FIG. 14 comprises a portion of an intermediate layer 37 which is disposed adjacent to the top surface of the storage electrode 35. An electrically conducting material 44 which is made of polysilicon is disposed on top of the intermediate layer. The electrically conducting material is different from the material of the intermediate layer. The electrically conducting material 44 laterally extends beyond the sidewalls of the storage electrode. Part of the electrically conducting material 44 is disposed on the horizontal surface of the semiconductor substrate 1. Optionally, a further barrier layer may be disposed at the boundary between the substrate surface and the electrically conducting material 44. For example, such a barrier layer may comprise a silicon nitride layer having a thickness not exceeding 1 nm so as to provide an electrical connection between the substrate and the electrically conducting material 44. This barrier layer may be formed by a nitridation step, for example, and may act as a diffusion barrier. As can further be seen from FIG. 14, the electrical contact area between the conducting material 44 and the storage electrode 35 is disposed at the height of the semiconductor substrate surface 10.

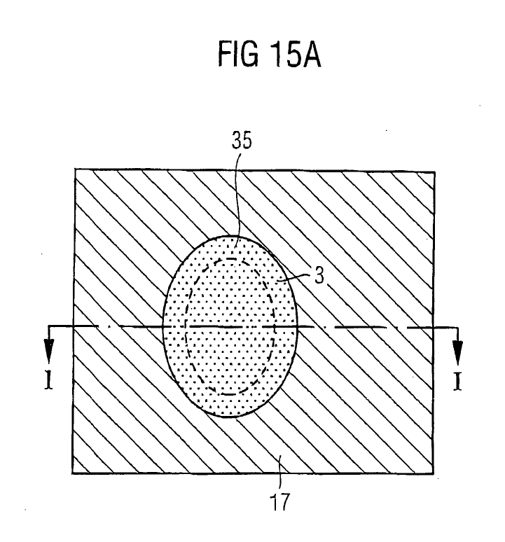

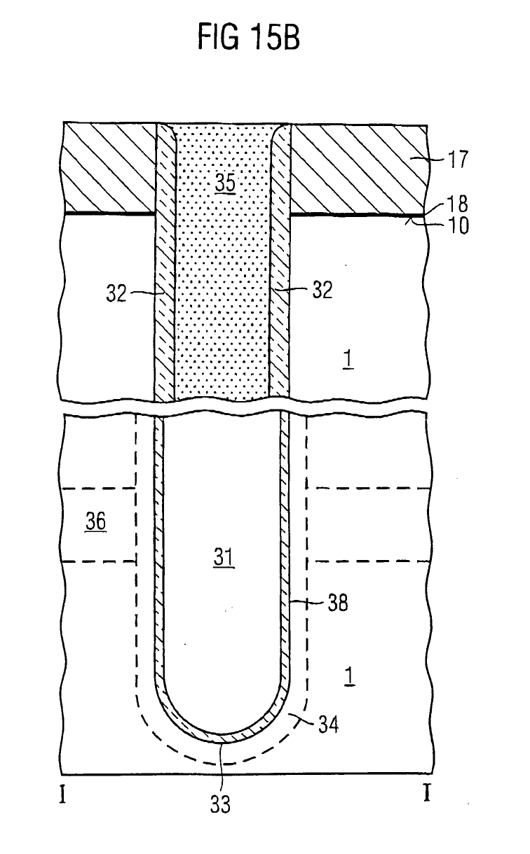

FIGS. 15A to 30 illustrate a second embodiment of the present invention in which the connection is designed close to the surface, however, not essentially protruding above the substrate surface as presented in the following. This results in the special advantage that a memory cell array with such a connection has a more favorable topology than a connection which entirely passes over the substrate surface. The starting point for the completion of the second embodiment is again a storage capacitor which is designed as a trench capacitor, analogously to the trench capacitor presented in FIGS. 2A and 2B. A top view on the trench capacitor is shown in FIG. 15A while FIG. 15B shows a cross-sectional view of the trench capacitor. The manufacture of the trench capacitor shown in FIGS. 15A and 15B will be performed analogously to the method as it has been described with reference to FIGS. 2A and 2B. However, as shown in FIG. 15B, the isolation collar 32 according to the second embodiment is designed such that it reaches up to the surface of the silicon nitride layer 17. In other words, for manufacturing the trench capacitor shown in FIG. 15B, the capacitor trench 38 will be filled—after forming the isolation collar 32—with a polysilicon filling 35, and subsequently, a CMP step is performed. In contrast to the method presented with reference to FIG. 2B, the steps for etching back the polysilicon filling 35 as well as the etching back of the isolation collar 32 are inapplicable here.

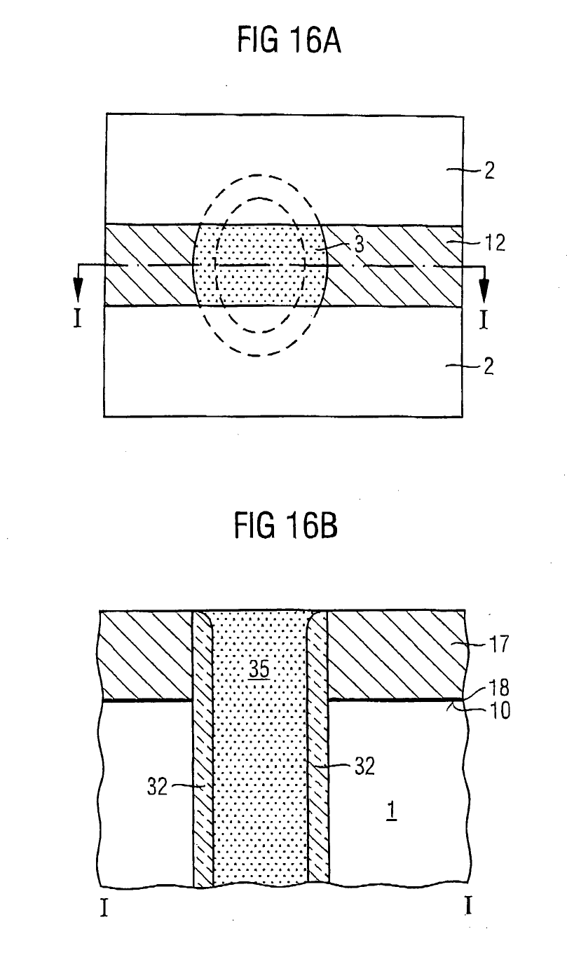

Referring to FIGS. 16A and 16B, starting from the structure presented in FIGS. 15A and 15B, in a next step for the definition of the active regions 12, isolation trenches 2 are formed which are filled up with an insulating material, especially silicon dioxide, as has been described with reference to FIGS. 3A and 3B. FIG. 16A shows a top view on the resulting trench capacitor 3 with the isolation trenches 2, and FIG. 16B shows a cross-sectional view along the line which connects the points I and I with each other.

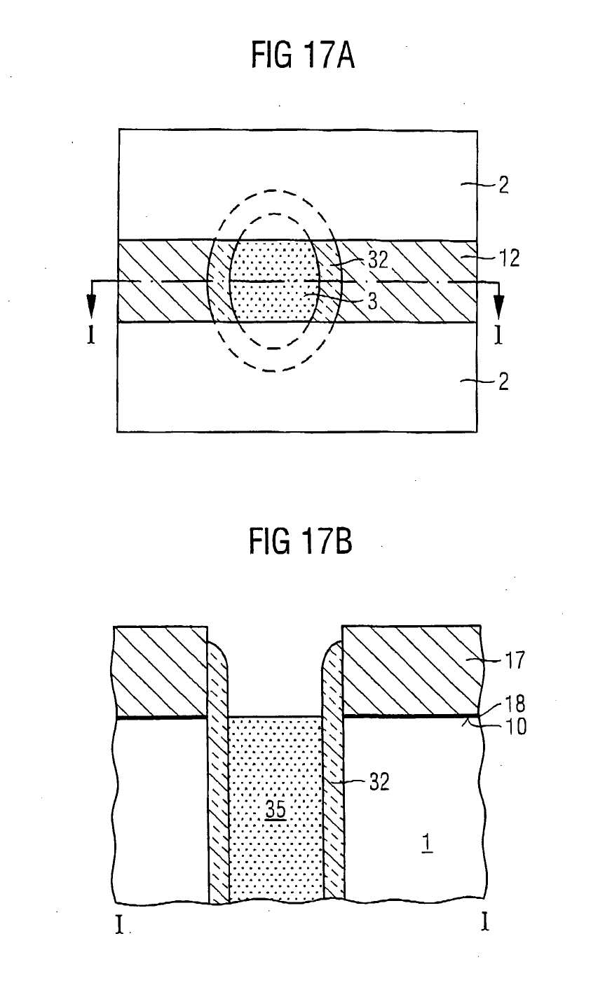

As shown in FIGS. 17A and 17B, the polysilicon 35 filled into the capacitor trench 38 is subsequently etched back to about the level of the substrate surface 10. More precisely, the target etching depth is 0 nm relative to the substrate surface 10 with a tolerance of +15 nm. FIG. 17A shows a top view of the resulting trench capacitor, illustrating that the surface of the isolation collar 32 is now exposed. FIG. 17B shows a cross-sectional view along the line connecting the points I and I in FIG. 17A with each other. As can be seen in FIG. 17B, the surface of the isolation collar 32 is slightly below the surface of the silicon nitride layer 17.

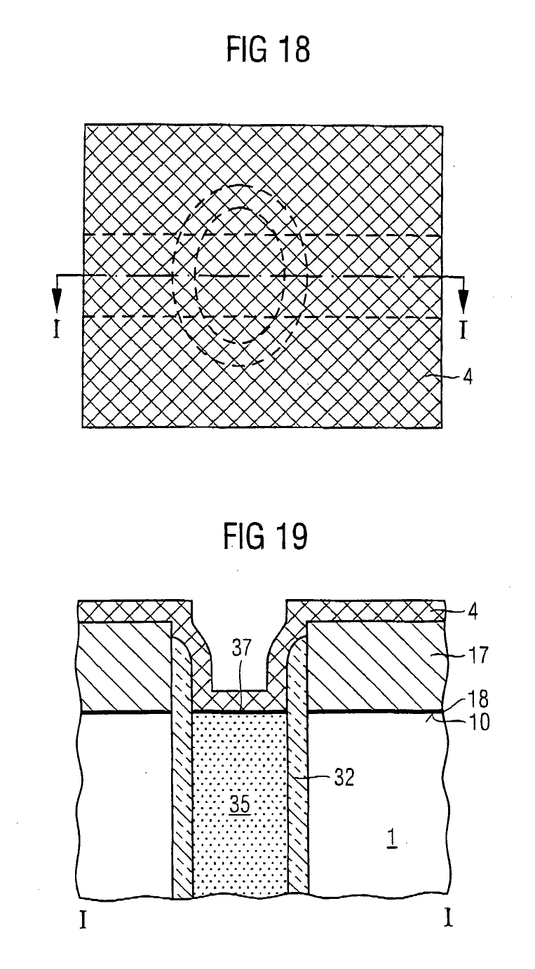

Referring next to FIGS. 18 and 19, a nitridation process is then performed, which is generally known. Here, a thin Si₃N₄ layer 37 is formed, typically with a thickness of up to 1 nm, such that the substrate surface will be exposed to a NH₃ atmosphere. This Si₃N₄ layer 37 serves as an etching stop layer with a subsequent etching step for etching the undoped amorphous semiconductor layer 4.

In a next step, an undoped amorphous semiconductor layer—preferably an undoped amorphous silicon layer—for example with a layer thickness of 10 nm will be conformally deposited. As a result, the deposited silicon layer 4, as shown in cross-section in FIG. 19, comprises vertical and horizontal as well as curved regions. FIG. 18 shows a top view on the resulting structure.

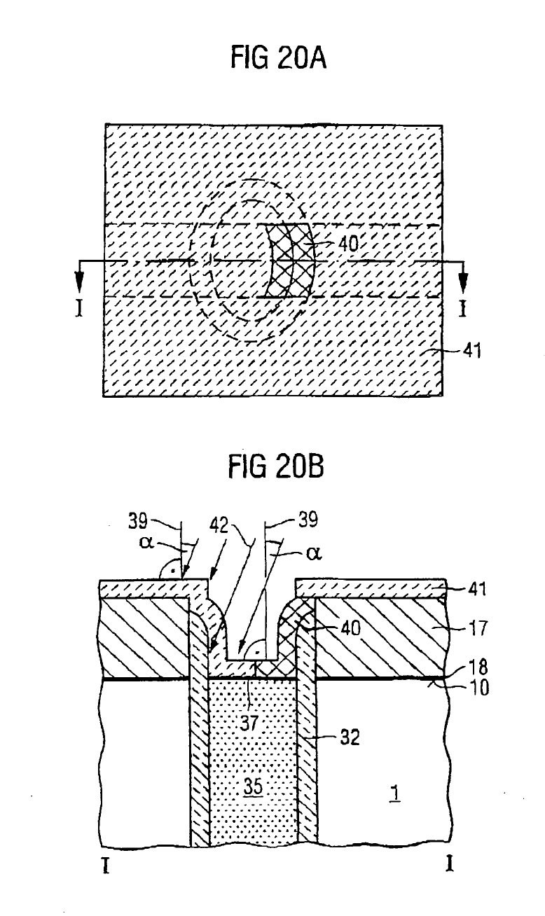

As shown in FIGS. 20A and 20B, in a manner analogous to the first embodiment, ion implantation is then performed with B+ or BF2+ ions with an oblique angle of incidence of the ion beam 42. For example, the ion beam 42 has an angle α of 5 to 25 degrees, in particular 10 to 15 degrees, in relation to the normal 39 to the substrate surface 10. As a result of the oblique ion implantation and the fact that the amorphous silicon layer 4 comprises vertical areas, one part of the amorphous silicon layer 4 will be shaded with this implantation step. In this case, the oblique ion implantation will be aligned such that the shaded area is located at the point at which the surface connection or, respectively, the connecting structure is to be made. More precisely, the angle of incidence of the ion beam 42 is selected such that the place at which the connecting structure is to be made will be suitably shaded. Due to the fact that the vertical area of the amorphous silicon layer 4 is shaded by the capacitor trench wall, asymmetrical processing will now take place. Consequently, the capacitor trench with connecting structure is now no longer symmetrical with regard to an axis which extends parallel to the direction of the capacitor trench.

FIGS. 20A and 20B respectively show a top view and a cross-sectional view along the line I-I shown in FIG. 20A. In particular, one part 40 of the amorphous silicon layer 4 remains undoped whereas the remaining areas having been exposed to the ion beam 42 will be doped. As illustrated in FIG. 20A, a section of the contour of the capacitor trench 38 remains undoped.

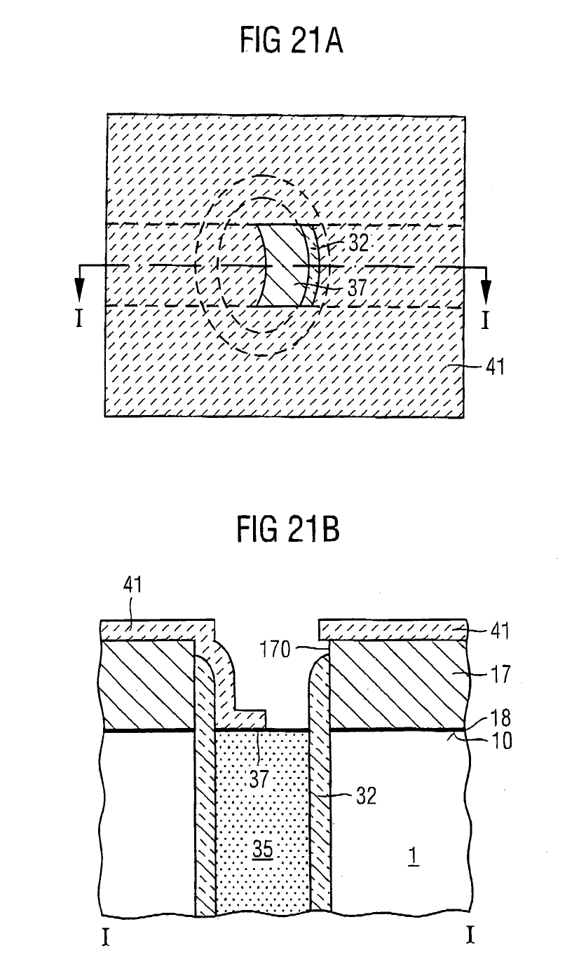

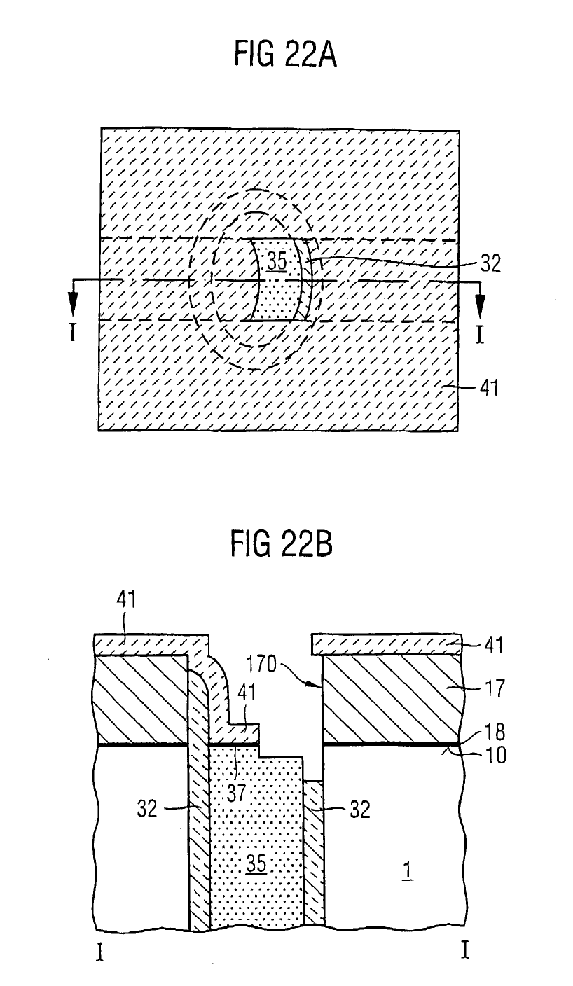

Referring next to FIGS. 21A and 21B, undoped amorphous silicon 4 is removed selectively with regard to the p-doped polysilicon resulting from the ion implantation. This can be accomplished, for example, by chemical wet etching in diluted NH4OH. With this etching step, the silicon nitride layer 37 serves as an etching stop. As is shown in FIG. 21A, one part of the silicon nitride layer 37 is now exposed. As is especially evident from FIG. 21B which shows a cross-sectional view along the line I-I in FIG. 21A, the lateral flank or sidewall of the upper part of the SiO2 isolation collar 32 is exposed in particular. Furthermore, one part of the lateral flank or sidewall of the Si₃N₄ layer 17 is exposed. As shown in FIGS. 22A and 22B, a reactive ion etching method is next performed by which the isolation collar 32 is etched back in the area which protrudes over the surface of the polysilicon filling 35. Due to the reactive ion etching, the exposed part of the Si₃N₄ layer 17 will also be etched off.

Subsequently, a short etching step in hydrofluoric acid is performed. With this etching step, the isolation collar 32 is etched back in particular such that the surface of the isolation collar is arranged as a result below the substrate surface 10 and a vertical area of the semiconductor substrate 1 is laterally exposed.

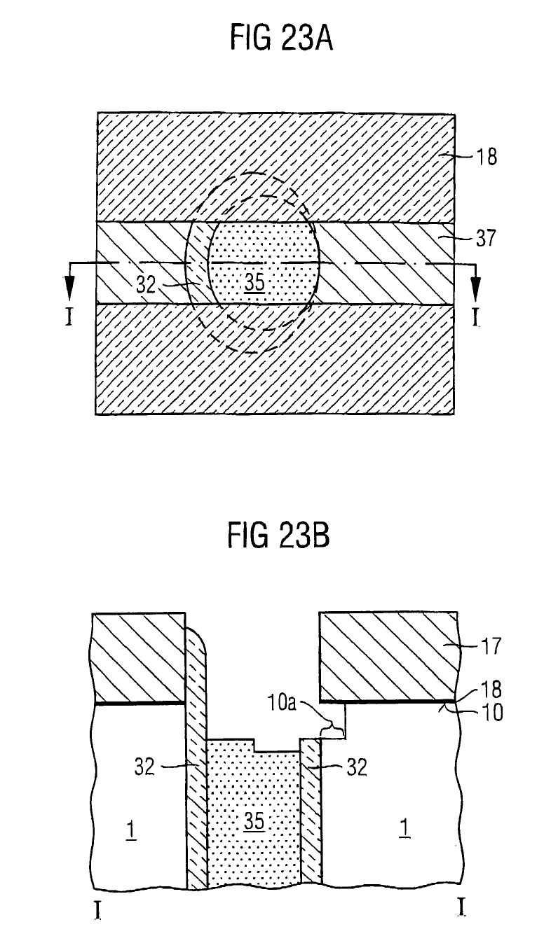

As seen in FIG. 22B, the isolation collar 32 is now etched back on the side on which the undoped silicon layer has been removed. Furthermore, the surface of the polysilicon filling 35 is partly exposed. The lateral flank 170 or sidewall of the Si₃N₄ layer 17 is now also exposed. Referring next to FIGS. 23A and 23B, the amorphous, p-doped silicon layer is then removed by an isotropic etching method, for example, a reactive ion etching method with fluoric chemicals. As shown in FIG. 23B, this etching step will also etch one part of the silicon substrate 1 so that finally a horizontal substrate surface section 10a is exposed.

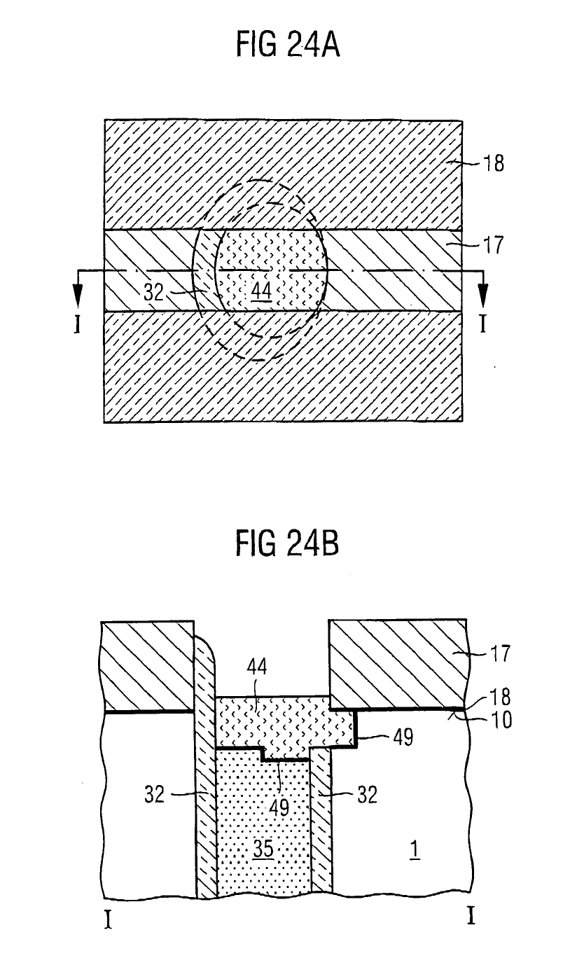

As shown in FIGS. 24A and 24B, a nitridation step is next performed, as described above, with the silicon nitride layer 49 being produced which serves as a diffusion barrier. Subsequently, a polysilicon filling 44—which can be doped with phosphor for example—will be filled in and etched back. FIG. 24A is a top view of the resulting structure, whereas FIG. 24B shows a cross-sectional view of the structure.

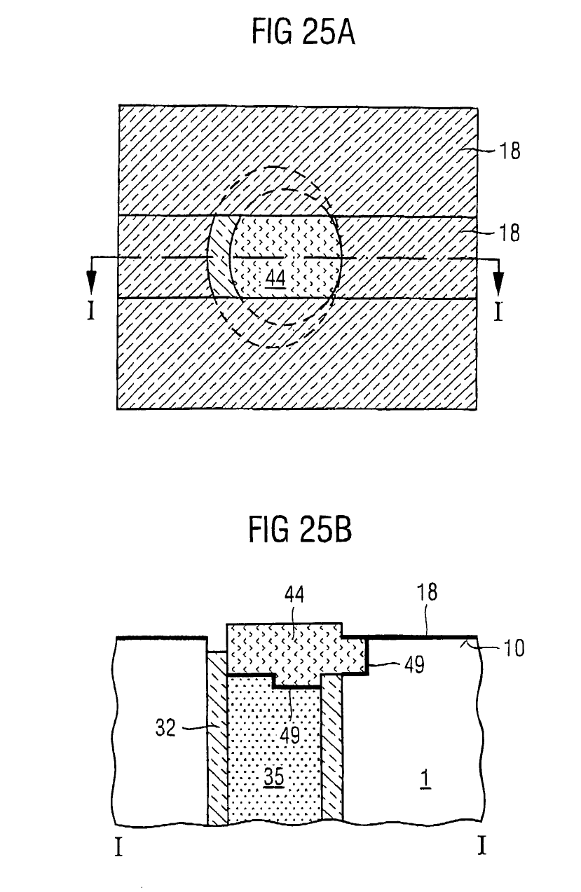

As shown in FIG. 24B, the polysilicon layer is etched back to somewhat above the substrate surface 10. After deglazing for the removal of surface oxide, the silicon nitride layer 17 is removed from the substrate surface 10, as shown in FIGS. 25A and 25B, which respectively show a top view and a cross-sectional view of the resulting manufactured structure. As shown in FIG. 25B, the polysilicon filling 44 now protrudes somewhat above the surface 10 of the silicon substrate 1. The polysilicon filling 44 is connected via the silicon nitride layer 49 in each case with the polysilicon filling 35 of the trench capacitor as well as with the silicon substrate 1. The silicon nitride layer 49 serves as a tunnel barrier in each case. The surface of the silicon substrate 10 is covered with a thin silicon dioxide layer 18. This is also illustrated in FIG. 25A which shows that nearly the entire surface—with the exception of the polysilicon regions 44—is covered with a thin silicon oxide layer 18.

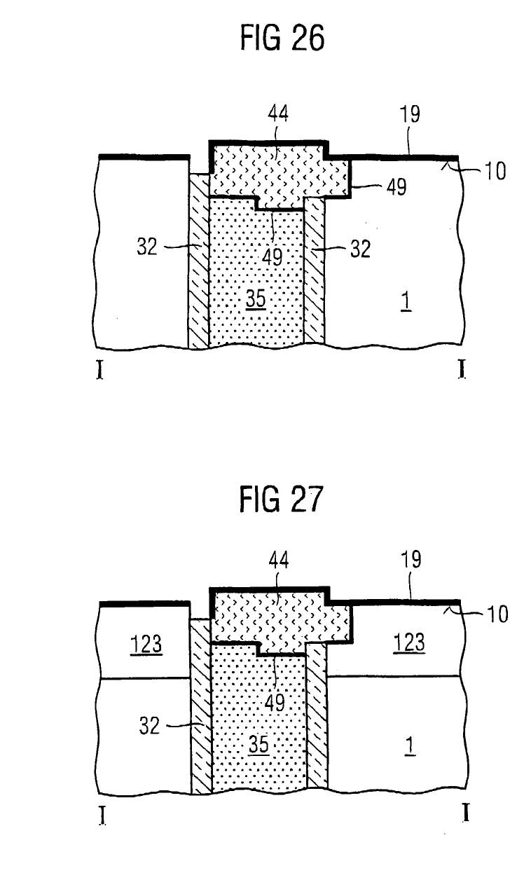

Referring to FIG. 26, the thin silicon dioxide layer 18 is then removed from the entire surface and a silicon dioxide layer 19 is produced by oxidation, for example, by exposing the resulting surface to a highly oxidizing atmosphere. As shown in FIG. 26, the entire surface is now covered by the silicon dioxide layer 19.

Referring next to FIG. 27, a photo-lithographic mask is subsequently formed in the usual manner, which covers up the peripheral portion area of the storage device. Subsequently, the usual doping steps are performed for producing the well portions. Next, the high and low doped regions 123 are produced, e.g., through ion implantation with phosphor or arsenic ions, from which the first and the second source/drain region will result in a later process step. FIG. 27 illustrates that the doped region 123 is formed in a portion which is adjacent the surface 10 of the semiconductor substrate 1. The doped region 123 extends to below the bottom edge of the polysilicon filling 44.

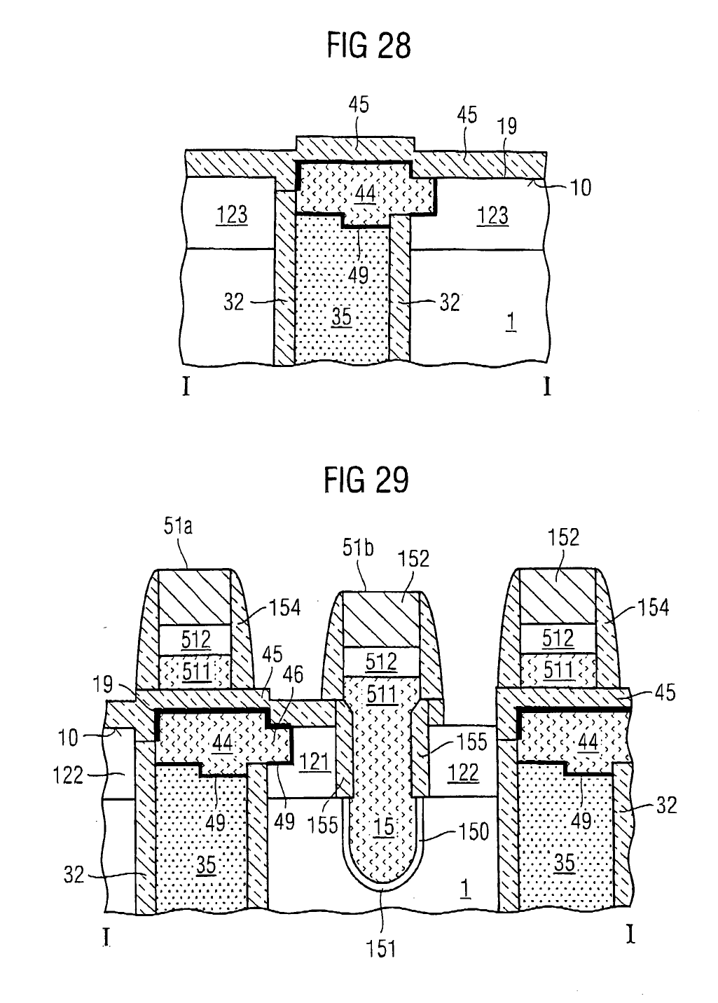

As shown in FIG. 28, a thick silicon dioxide layer 45 with a layer thickness of 10 to 20 nm is then formed which effects an insulation of the polysilicon filling 44 and thus the storage electrode of the trench capacitor against the passing word line to be formed above the trench 38. After removal of the implantation mask in the peripheral portion, the SiO2 layer 45 is removed from the peripheral portion. Subsequently, the corresponding doping steps for the peripheral portion are performed.

Referring now to FIG. 29, a transistor is subsequently formed in the usual manner in the active region 12. In particular, for producing the gate electrode 15, a gate groove 150 can be formed in which a gate insulating layer 151 will be formed. Subsequently, an inner spacer 155, preferably of SiO₂, is formed, and the gate groove 150 is filled in the usual manner with a polysilicon filling 511. Subsequently, the polysilicon layer 511, the tungsten layer 512, as well as the Si₃N₄ layer 152 are deposited in the usual manner. After corresponding patterning of the word line, spacers are formed, e.g., SiO₂ spacers 154, so that finally the structure presented in FIG. 29 is obtained.

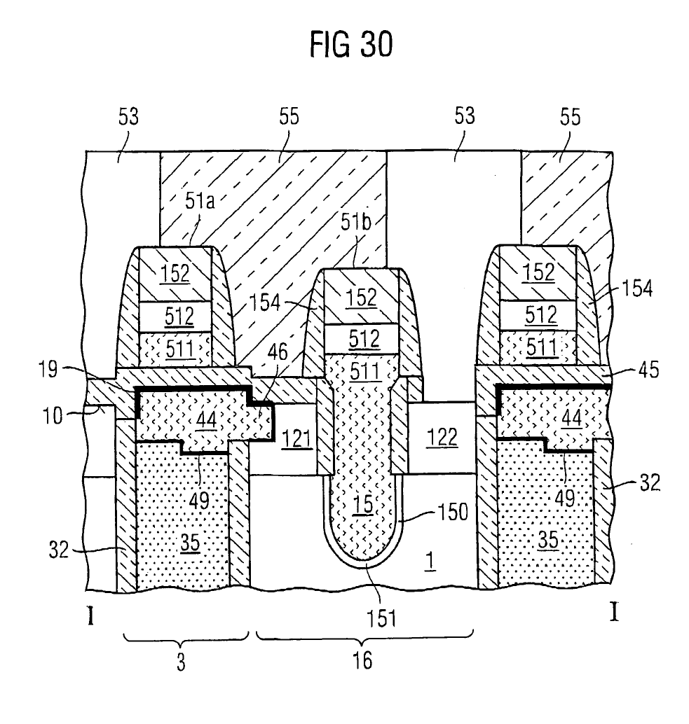

Finally, as shown in FIG. 30, bit line contacts 53 can be made, for example, by a method in which sacrificial polysilicon plugs are provided at the positions at which the contacts are to be formed which are insulated from each other by an insulating layer, e.g., a BPSG layer 55. FIG. 30 shows an exemplified cross-sectional view of a memory cell array with memory cells which each comprise a trench capacitor 3 as well as a access transistor 16, in which the first source/drain region 121 each of the access transistor is connected with the storage electrode of the trench capacitor 3 via the surface strap connection 46 according to the invention and the polysilicon filling 35. A thin Si₃N₄ layer 49 is arranged in each case between the polysilicon filling 35 and the polysilicon filling 44 and, respectively, between the first source/drain region 121 and the polysilicon filling 44. However, this thin Si₃N₄ layer 49 merely serves as a thin tunnel barrier and is thus not suitable to electrically isolate the polysilicon filling 35 from the polysilicon filling 44 or, in turn, the first source/drain region 121 from the polysilicon filling 44. The surface strap connection 46 is provided in a region near of the surface of the substrate 1. Consequently, the surface of the connection 46 is adjacent the substrate surface 10 and slightly protrudes above it. Thus, the connection is not realized entirely above the substrate surface 10; however, it also does not extend entirely below the substrate surface 10. Rather, the surface connection 46 extends so far above the surface that its advantageous effects with regard to the properties of the transistor 16 will be used, whereas the disadvantage associated with such a surface connection will be avoided, namely, the resulting unfavorable topology of the memory cell array. As can be seen for example in FIG. 30, the upper edge of the passing word line 51a is provided slightly above the upper edge of the active word line 51b, and the surface is completely leveled by the BPSG layer 55. The transistor 16 is designed as a so-called “recessed channel transistor” in which the gate electrode 15 is formed in a gate groove 150. Thus, the channel length between the first and the second source/drain region 121, 122 will be increased in an advantageous manner with an unchanged space requirement of the memory cell.

The connecting structure shown in FIG. 30 comprises a portion of an intermediate layer 49 which is made of silicon nitride. The portion of the intermediate layer 49 is disposed on top of the storage electrode 35 of the storage capacitor. Further, the connecting structure comprises an electrically conducting material 44 which is made, for example, of polysilicon. The electrically conducting material is different from the material of the intermediate layer. The conducting material 44 is disposed on top of the intermediate layer 49. The conducting material 44 laterally extends beyond the trench delimiting the storage electrode 35. Moreover, part of the conducting material 44 is disposed on a horizontal surface of the semiconductor substrate. Optionally, a further barrier layer may be disposed at the interface between the substrate material and the conducting material 44. The further barrier layer may, for example, be made of silicon nitride having a thickness not exceeding 1 nm so as to establish an electrical contact between the substrate material and the electrically conducting material. The further barrier layer acts as a diffusion barrier.

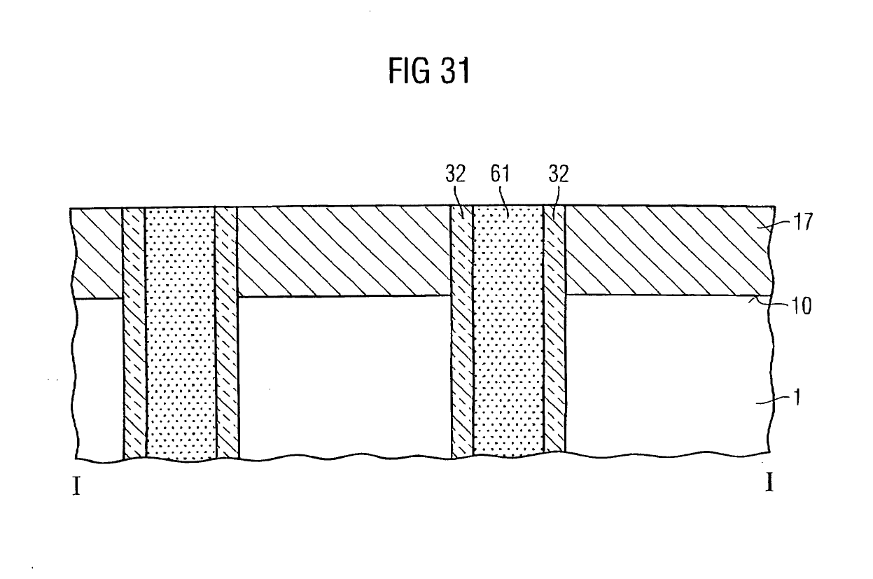

FIGS. 31 to 41 illustrate a third embodiment of the present invention. In this exemplary embodiment, the conductive strap material is disposed adjacent to a lateral surface of the storage electrode of the storage capacitor.

FIG. 31 shows a cross-sectional view of the upper portion of a substrate surface 1, when starting the method of the third embodiment. As can be seen, on the substrate surface 10, a silicon nitride layer 17 is formed. Trenches 33 are formed in the substrate surface 10. An isolation collar 32 is formed in the upper portion of the trench, and a filling 61 is provided, so that the surface of the trenches is completely closed. Differently stated, a plane surface is obtained. The filling 61 may be the storage electrode of the storage capacitor or a sacrificial filling which will be removed after completing the memory cell array.

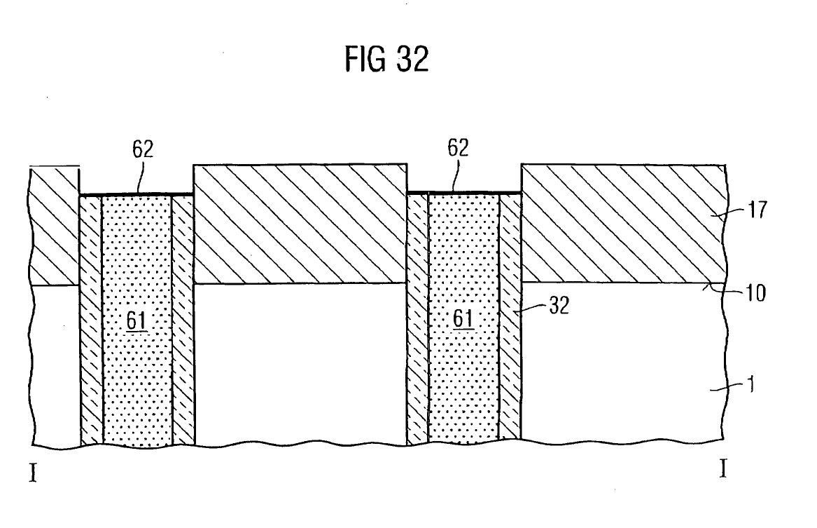

Starting from the structure shown in FIG. 31, first, an etching step is performed so as to etch the upper portion of each of the isolation collars 32. Thereafter, the sacrificial filling 61 is recessed by a commonly used etching method. Thereafter, an oxidation step is performed so as to provide a thin silicon dioxide layer 62 having a thickness of approximately 1 to 3 nm. The resulting structure is shown in FIG. 32. As can be seen, the surface of the filling 61 is covered with the silicon dioxide layer 62. Furthermore, the surface of the silicon dioxide layer 62 is recessed with respect to the surface of the silicon nitride layer 17.

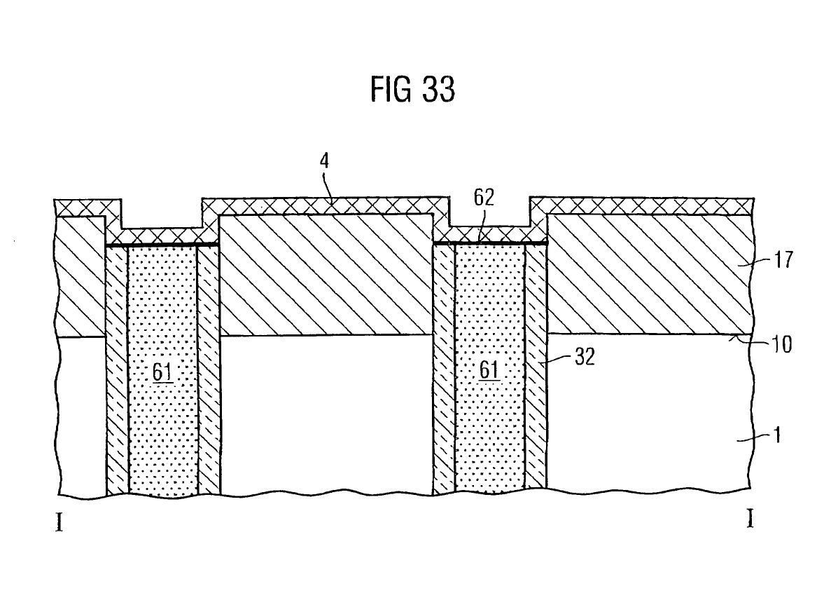

Thereafter, an undoped amorphous silicon layer 4 having a thickness of approximately 10 to 15 nm is deposited. For example, the amorphous silicon layer 4 may have a thickness of 12 to 14 nm. The resulting structure is shown in FIG. 33.

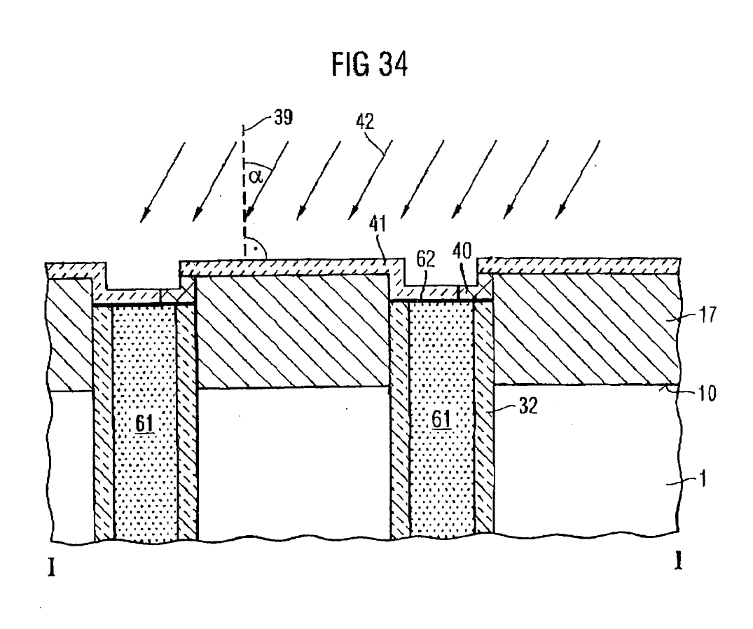

In the next step, a tilted ion implantation step 42 is performed. During this ion implantation step, an angle α of the ion beam 42 with respect to the normal on the substrate surface 39 may be approximately 5 to 30°. During this ion implantation step part of the ion beam is shadowed by the protruding portions of the silicon nitride layer 17 and amorphous silicon layer 4. Accordingly, predetermined portions of the undoped amorphous silicon layer will be doped whereas other predetermined portions remain undoped. For example, this ion implantation step may be performed with a p-dopant, for example BF2-ions. The resulting structure is shown in FIG. 34. As can be seen from FIG. 34, portions 40 of the amorphous silicon layer 4 remain undoped, these portions being adjacent to a left hand edge of each of the protruding silicon nitride layer portions 17.

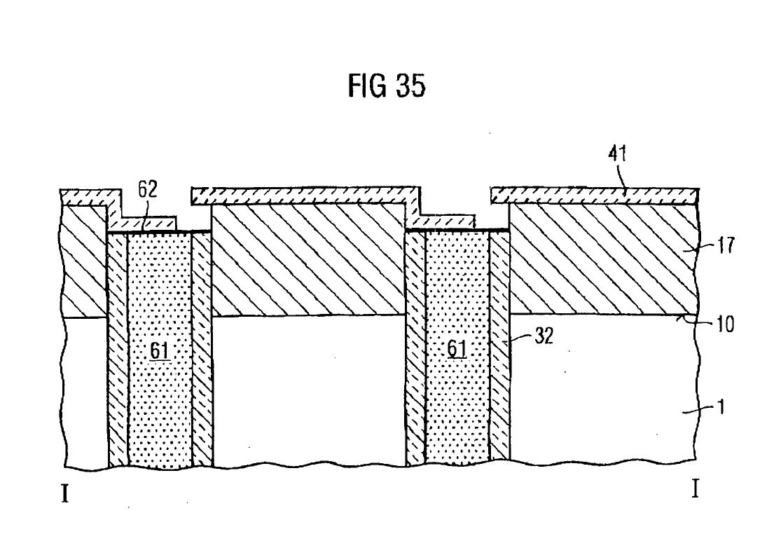

In the next step, an etching step for etching the undoped amorphous silicon selectively with respect to doped amorphous silicon is performed. For example, this may be accomplished by etching with NH4OH. The resulting structure is shown in FIG. 35. As can be seen, on the right hand side of each of the trenches the undoped amorphous silicon layer 40 is removed.

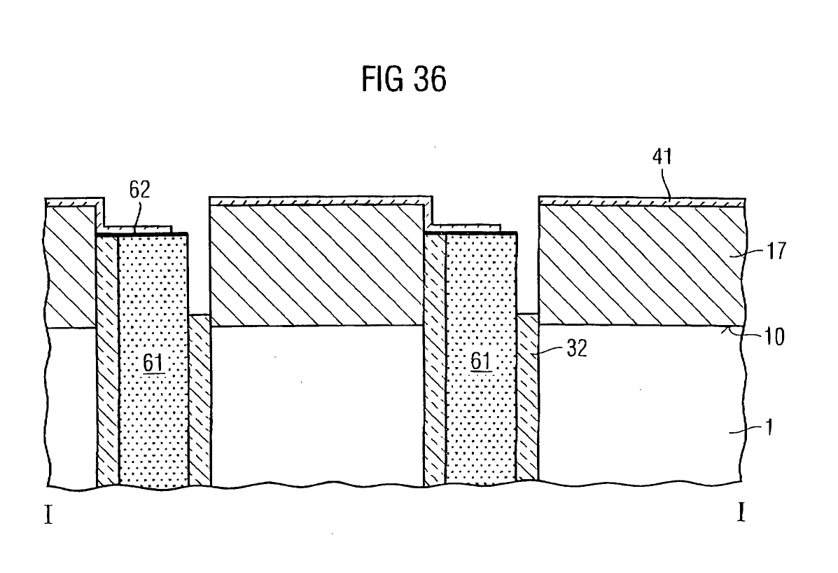

Thereafter, an etching step is performed which etches silicon dioxide selectively with respect to polysilicon. As a result, the collar portion 32 is recessed at those portions which are not covered with the silicon layer 41. In particular, this etching step is performed so that the collar is not recessed to a position below a position which is beneath the surface 10 of the semiconductor substrate. For example, approximately 85 to 115 nm may be etched. The resulting structure is shown in FIG. 36. As can be seen, in the right hand portion of each of the trenches 33, the collar is recessed, so that the resulting surface of the collar is disposed above the substrate surface 10. Moreover, the thickness of the amorphous silicon layer 41 is reduced.

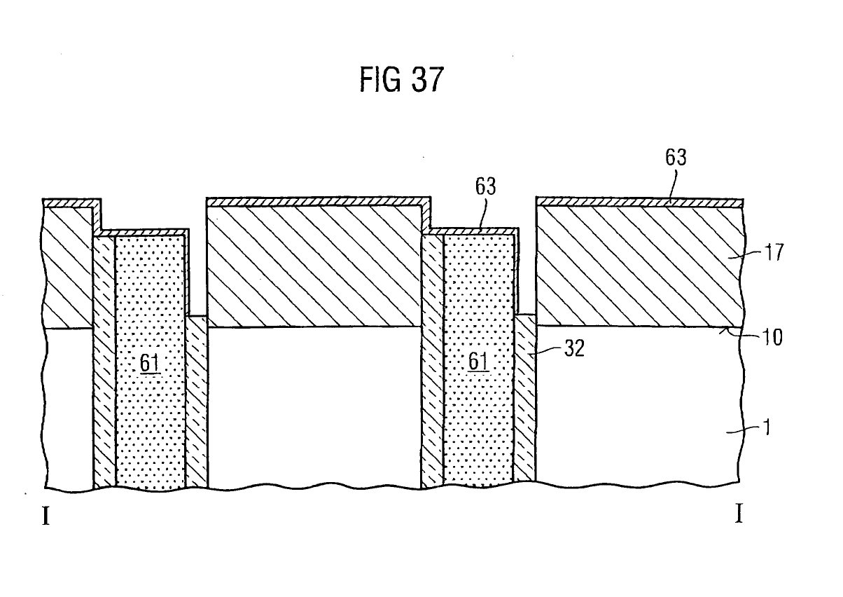

After performing a pre-cleaning step, so as to remove polymer residuals, an oxidation step is performed so as to provide the silicon dioxide layer 63. In particular, this oxidation step oxidizes the amorphous doped silicon layer 41 to result in the silicon dioxide layer 63. The resulting structure is shown in FIG. 37.

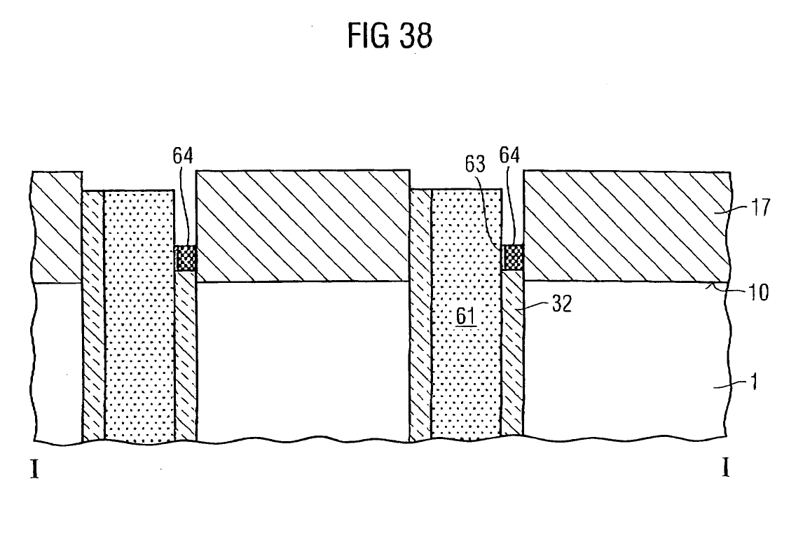

In the next step a conductive layer is deposited. For example, the conductive layer may comprise any material which might be suitable for a surface strap formation. By way of example, polysilicon, a metal, a metal silicide, for example, WSix (tungsten silicide) may be used as the conductive strap material. Thereafter, a recessing step is performed so as to etch the conductive material. As a result, only a portion of the conductive material remains above the recessed portion of the collar 32. For example, when WSix is taken as the conductive material, the WSix may be wet etched with a suitable etchant such as a mixture of H2O, H2O2 and NH4OH. Alternatively, the WSix may be etched dry with SF6 chemistry. The resulting structure is shown in FIG. 38. As can be seen, a conductive strap material 43 is provided in a portion between the filling 61 and the silicon nitride layer portion 17. The conductive strap material is entirely disposed above the substrate surface 10. Optionally, the silicon dioxide layer 63 still is remaining between the conductive strap material and the filling 61. For example, if the filling is a sacrificial filling, the remaining silicon dioxide layer 63 may be removed when removing the sacrificial filling. Nevertheless, due to the small thickness, the remaining silicon dioxide layer 63 may as well be conductive.

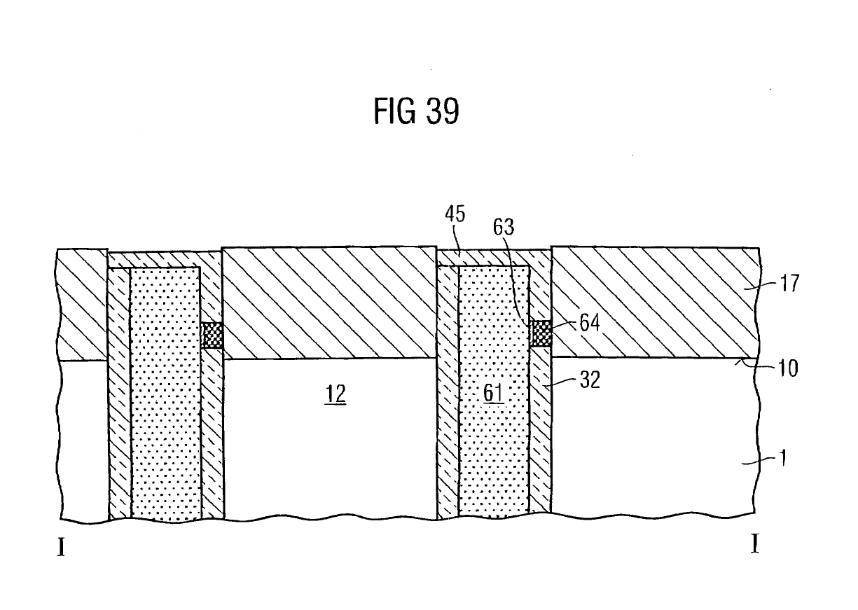

Thereafter, an insulating material 45, for example, a silicon dioxide layer is provided, followed by a CMP step. For example, the silicon dioxide layer may be thermally grown or be deposited by a suitable method. As a result, the surface of the filling 61 is covered with the silicon dioxide layer 45, as is shown in FIG. 39.

Thereafter, the memory cell array will be completed as is generally known. For example, starting from the structure shown in FIG. 39, a portion of the silicon nitride layer can be removed so as to laterally expose the conductive strap material 64. Thereafter, a suitable conductive material 65 is provided in the opened portion. For example, the conductive material 65 may be doped polysilicon. Thereafter, the essential components of an access transistor are provided. For example, doped portions are formed, thus establishing the first and second source/drain portions. Moreover, a gate electrode is provided. For example, the gate electrode 15 may be disposed in a gate groove extending in the substrate surface 10. A gate insulating material 151 is provided, and a sidewall spacer may be provided in the gate groove. Finally, the gate groove 150 is filled with an electrically conductive material so as to complete the transistor. Thereafter, the word lines 51a, 51b are provided as is common. In addition, bit line contacts as well as bit lines are provided. Optionally, if the filling 61 is a sacrificial filling, the sacrificial filling is removed from the trench and replaced with another suitable conductive material.

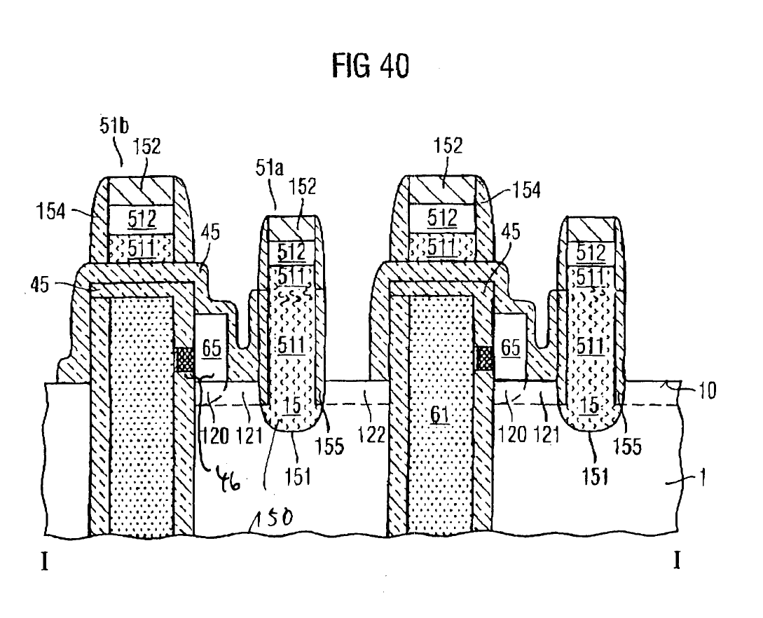

The resulting structure is shown in FIG. 40. As can be seen, a diffused area 120 is formed in the semiconductor substrate 1 beneath the conductive material 65. Accordingly, an electrical contact is established between the storage electrode 61 and the first source/drain region 121 of the access transistor 16 of the memory cell. The connecting structure comprises an intermediate layer 64 representing the conductive strap material. Moreover, the connecting structure comprises the electrically conducting material 65. The intermediate layer 64 is disposed adjacent to a lateral surface of the filling 61 of the trench. The filling 61 of the trench may be made of an arbitrary conductive material. For example, the material of the filling 61 may comprise polysilicon, metal or metal compounds. The conducting material 65 is disposed above the semiconductor substrate surface so as to be adjacent to a horizontal substrate surface portion.

Differently stated, as can be seen from FIG. 40, the conductive filling 61 is disposed in a trench formed in the substrate surface 10. Moreover, the electrically conducting material 65 is completely disposed outside the trench formed in the substrate surface 10. Moreover, also the intermediate layer 64 is completely disposed outside the trench formed in the substrate surface 10. Furthermore, the vertical surface of the storage electrode of the trench capacitor is laterally delimited by an isolating trench. In particular, this isolating trench is arranged between the storage electrode and the semiconductor substrate. An insulating material, i.e. the isolation collar 32, is disposed in the isolating trench. As can be seen from FIG. 40, the connecting structure comprises a strap 64 of a conductive material which is disposed in the isolating trench.

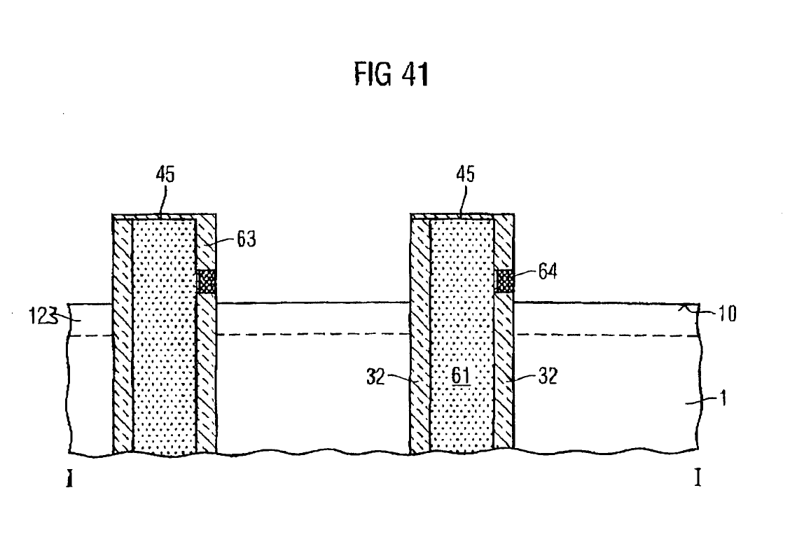

Nevertheless, as is clearly to be understood, starting from the structure shown in FIG. 39, the memory cell array can be completed in an arbitrary manner. For example, the silicon nitride layer 17 may be removed. Thereafter, an ion implantation step with n dopants is performed so as to provide the doped area 123. The resulting structure is shown in FIG. 41. As can be seen, now protruding trench structures are present. The trench structures protrude from the substrate surface 10. The filling 61 is covered with the silicon dioxide layer 45 on the top side thereof. A conductive strap material 43 is provided at the lateral portion so as to enable an electrical contact. The conductive strap material 43 is positioned above the substrate surface 10. The doped portion 124 is disposed adjacent to the substrate surface 10. Thereafter, the memory cell array will be completed by providing a gate electrode, word lines connecting the gate electrodes, bit lines as well as bit line contacts.

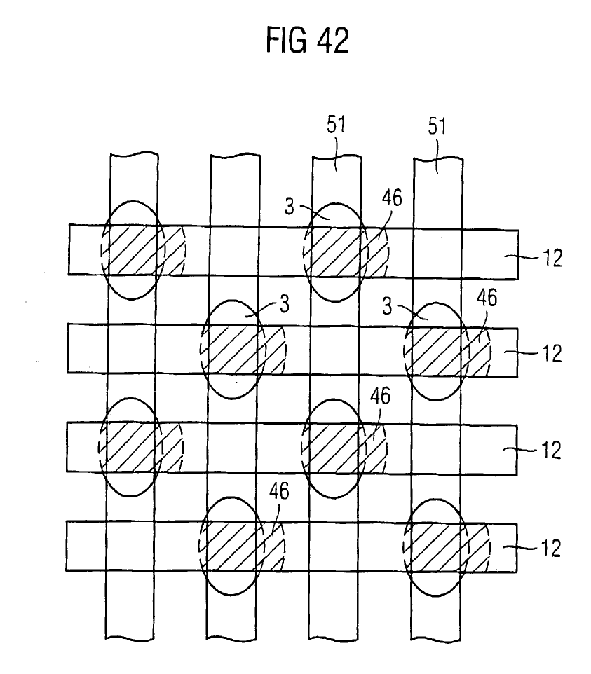

FIG. 42 shows a top view of an exemplified memory cell array in which the storage electrodes of the trench capacitors are each connected via a surface strap connection 46 with the access transistor. Active areas 12 are arranged in strip form and are insulated from each other by isolation trenches 2. The trench capacitors 3 are arranged checker-board style in FIG. 15. However, it is evident that the present invention can also be used with alternative layouts. Perpendicular to the active regions, word lines 51 are provided which are each connected with the gate electrodes which control the conductivity of the channel 14 formed in the transistor.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SIGNS

1 Semiconductor substrate
10 Substrate surface
10a Uncovered semiconductor substrate surface section
12 Active region
120 Diffused area
121 First source/drain region
122 Second source/drain region
123 Doped area
14 Channel
15 Gate electrode
150 Gate groove
151 Gate insulating layer
152 Si3N4 capping layer
153 Si3N4 spacer
154 SiO2 spacer
155 Inner spacer
16 Transistor
17 Si3N4 layer (pad nitride)
170 Exposed area
18 SiO2 layer
19 SiO2 layer
2 Isolation trench
3 Trench capacitor
31 Storage electrode
32 Isolation collar
33 Capacitor dielectric
34 Counter electrode
35 Polysilicon filling
36 Buried plate
37 Si3N4 layer
38 Capacitor trench
39 Surface normal
4 □ silicon layer, undoped
40 Non-implanted area
41 p-doped □ silicon
42 Ion beam
43 Opening
44 Polysilicon
45 SiO2 layer
46 Surface strap connection
47 SiO2 layer
48 Diffusion area
49 Si3N4 layer
5 Memory cell
51a Passing word line
51b Active word line
52 Bit line
53 Bit line contact
54 Substrate connection
55 BPSG layer
511 Polysilicon
512 Tungsten layer
61 conductive filling
62 silicon dioxide layer
63 silicon dioxide layer
64 conductive strap material
65 conductive material

What is claimed is:

1. A connecting structure between a storage electrode of a trench capacitor and a selection transistor that are at least partially formed in a semiconductor substrate, the connecting structure comprising:
a portion of an intermediate layer disposed adjacent to a surface of the storage electrode; and
an electrically conducting material disposed adjacent to the intermediate layer and electrically connected to a semiconductor substrate surface portion adjacent to the selection transistor, wherein a part of the connecting structure is disposed above the semiconductor substrate surface so as to be adjacent to a horizontal substrate surface portion.

2. The connecting structure of claim 1, wherein the intermediate layer comprises an insulating material and has a thickness no greater than 1 nm.

3. The connecting structure of claim 2, wherein the intermediate layer comprises Si₃N₄ or silicon oxide.

4. The connecting structure of claim 1, wherein the intermediate layer comprises a conductive material.

5. The connecting structure of claim 1, wherein the electrically conducting material comprises doped polysilicon.

6. The connecting structure of claim 1, wherein the electrically conducting material is disposed substantially above the substrate surface.

7. The connecting structure of claim 1, wherein the electrically conducting material is disposed substantially below the substrate surface.

8. The connecting structure of claim 1, wherein the intermediate layer is disposed on a top surface of the storage electrode.

9. The connecting structure of claim 1, wherein the storage electrode extends above the semiconductor surface.

10. The connecting structure of claim 1, wherein the intermediate layer is disposed adjacent to a lateral surface of the storage electrode.

11. The connecting structure of claim 1, wherein the storage electrode is laterally delimited by a trench formed in the substrate surface, the electrically conductive material being disposed outside the trench.

12. The connecting structure of claim 1, wherein the storage electrode is laterally delimited by a trench formed in the substrate surface, the portion of the intermediate layer being disposed outside the trench.

13. The connecting structure of claim 12, wherein the intermediate layer comprises the electrically conductive material.

14. The connecting structure of claim 1, wherein a contact between the storage electrode and the intermediate layer is disposed above the substrate surface.

15. The connecting structure of claim 1, wherein a contact between the storage electrode and the intermediate layer is disposed below the substrate surface.

16. The connecting structure of claim 1, further comprising a barrier layer disposed between the electrically conducting material and the substrate.

17. The connecting structure of claim 16, wherein the barrier layer comprises silicon nitride and has a thickness no greater than 1 nm.

18. A connecting structure between a storage electrode of a trench capacitor and a selection transistor that are at least partially formed in a semiconductor substrate, the connecting structure comprising:
a portion of an intermediate layer disposed adjacent to a surface of the storage electrode; and
an electrically conducting material disposed adjacent to the intermediate layer and electrically connected to a semiconductor substrate surface portion adjacent to the selection transistor, wherein the storage electrode is laterally delimited by a trench formed in the substrate surface, the electrically conducting material being disposed at least partially outside the trench.

19. The connecting structure of claim 18, wherein the portion of the intermediate layer is disposed outside the trench.

20. The connecting structure of claim 18, wherein the electrically conducting material is completely disposed outside the trench.

21. A connecting structure between a storage electrode of a trench capacitor and a selection transistor that are at least partially formed in a semiconductor substrate, wherein an isolating trench is disposed adjacent to a vertical surface of the storage electrode, the isolating trench being arranged between the storage electrode and the semiconductor substrate, an insulating material being disposed in the isolating trench, wherein the connecting structure comprises a strap of a conductive material which is disposed in the isolating trench.

22. The connecting structure of claim 21, further comprising a barrier layer disposed between the storage electrode and the strap of the conductive material.

23. The connecting structure of claim 21, wherein the strap of the conductive material is arranged above an upper surface of the semiconductor substrate.

24. The connecting structure of claim 23, further comprising a portion of a conductive layer which is disposed on the upper surface of the semiconductor substrate, the portion being in contact with the strap of conductive material.

25. The connecting structure of claim 21, wherein the strap of the conductive material is arranged below an upper surface of the semiconductor substrate.

26. The connecting structure of claim 21, wherein the conductive material comprises WSiₓ.

27. A method of manufacturing a connecting structure between a storage electrode of a trench capacitor and a selection transistor, comprising:
(a) providing a capacitor trench in a semiconductor substrate, the trench capacitor comprising a conductive filling, a vertical insulating layer being disposed adjacent to a lateral surface of the conductive filling;
(b) providing a masking material on a surface of the semiconductor substrate, the masking material being provided on areas of the substrate surface in which no trench capacitor is formed, wherein a surface of the conductive filling of the trench capacitor is disposed beneath a surface of the masking material;
(c) depositing a semiconductor layer that is undoped, the semiconductor layer comprising vertical and horizontal areas;
(d) performing oblique ion implantation such that a predetermined area of the semiconductor layer remains undoped;
(e) removing an undoped portion of the semiconductor layer, with a doped portion of the semiconductor layer remaining on a surface of the masking material, thereby leaving a surface of the vertical insulating layer uncovered;
(f) etching an upper portion of the vertical insulating layer, thereby forming a connection opening;
(g) filling a conductive material in the connection opening; and
(h) removing the masking layer thereby exposing a semiconductor substrate surface portion.

28. The method of claim 27, wherein a top surface of the conductive filling is disposed above the semiconductor substrate surface.

29. The method of claim 27, further comprising depositing an electrically conductive material on the exposed semiconductor substrate surface portion, the conductive material being in contact with the connection material as well as the with a component of the selection transistor.

30. The method of claim 27, wherein a top surface of the conductive filling is disposed below the semiconductor substrate surface.

31. The method of claim 27, wherein after (f), the substrate surface is exposed to an oxidizing atmosphere so as to oxidize a doped portion of the semiconductor layer.

32. The method of claim 27, wherein the connection material is selected from the group consisting of doped silicon and tungsten silicide.

33. The method of claim 27, wherein the material of the conductive filling comprises doped polysilicon.
